(19) United States
(12) Patent Application Publication
(10) Pub. No.: US 2005/0196710 A1
(43) Pub. Date: Sep. 8, 2005

(54) Method for forming pattern, thin film transistor, display device and method for manufacturing the same, and television apparatus

(75) Inventor: Hiroko Shiroguchi, Atsugi (JP)

Correspondence Address: NIXON PEABODY, LLP, 401 9TH STREET, NW, SUITE 900, WASHINGTON, DC, 20004-2128, US

(73) Assignee: Semiconductor Energy Laboratory Co., Ltd., Atsugi-shi (JP)

(21) Appl. No.: 11/060,699

(22) Filed: Feb. 18, 2005

(30) Foreign Application Priority Data
Mar. 4, 2004 (JP) 2004-061102

(51) Int. Cl. G03F 7/00

(52) U.S. Cl. 430/322; 430/320; 430/324

(57) ABSTRACT

It is an object of the present invention to provide a display device in which a material usability is enhanced and which can be manufactured by simplifying the manufacturing process, and a manufacturing technique thereof. It is also an object of the invention to provide a technique in which a pattern of a wiring or the like constituting these display devices can be formed to have a desired shape with preferable controllability. A method for forming a pattern according to the invention comprising the steps of: forming a first region including a light-absorbing material; forming a second region by modifying a surface of the substrate by irradiating the substance with laser light having a wavelength which is absorbed by the light-absorbing material; and forming a pattern by discharging a compound including a pattern forming material to the second region.

### BACKGROUND OF THE INVENTION

1. Field of the Invention

The present invention relates to a method for forming a pattern, a thin film transistor and a manufacturing method thereof, a display device and a manufacturing method thereof, and a television apparatus using thereof.

2. Description of the Related Art

A thin film transistor (hereinafter, referred to as a “TFT”) and an electronic circuit using the thin film transistor are manufactured by laminating various types of thin films of a semiconductor, an insulating material, a conductive material, and the like over a substrate and then, appropriately forming a predetermined pattern with a photolithography technique. The photolithography technique means a technique of transferring a pattern of a circuit or the like formed over a surface of a transparent flat plane, referred to as a photomask, by using a material which does not transmit light, onto a targeted substrate by utilizing light, and the technique has been widely used in the manufacturing process of a semiconductor integrated circuit or the like.

In the manufacturing process employing a conventional photolithography technique, it is necessary to perform a multi-stage process including light exposure, development, baking, peeling, and the like only for treating a mask pattern which is formed by using a photosensitive organic resin material referred to as a photoresist. Therefore, as the number of the photolithography step is increased more, the manufacturing cost is inevitably increased more. In order to improve such problems as described above, it has been tried to manufacture a TFT by reducing the number of the photolithography step (for example, Reference 1: Japanese Patent Laid-Open No. H11-251259).

However, in the technique disclosed in Reference 1, only a part of the photolithography step which is carried out plural times in a TFT manufacturing process is replaced by a printing method and no contribution is made to a drastic reduction in the number of steps. Further, a light exposing apparatus to be used for transferring the mask pattern in the photolithography technique transfers a pattern of from several micrometers to 1 micrometer or less by equivalent projection light exposure or reduction projection light exposure. It is theoretically difficult for the light exposing apparatus to expose a large area substrate having a side of more than 1 meter to light all at once from a technical standpoint.

### SUMMARY OF THE INVENTION

It is an object of the present invention to provide a technique in which, in the manufacturing process of a TFT, an electronic circuit using the TFT, and a display device formed by using the TFT, the manufacturing process is simplified by reducing the number of the photolithography step and in which a large area substrate having a side of more than 1 meter can be manufactured with a higher yield at lower cost.

It is also an object of the invention to provide a technique in which a pattern of a wiring or the like constituting these display device can be formed to have a desired shape with preferable controllability.

In the present invention, pattern indicates a circuit pattern, a mask pattern, a wiring pattern, an electrode pattern or the like, but the invention is not limited to them.

According to the invention, a light-absorbing material which absorbs the wavelength of laser light which is to be radiated is added (mixed) into a processing object to be irradiated with the laser light to modify the surface of the processing object. Then, a pattern forming material is attached on the modified surface by a discharge method (including an applying method or the like), or the like to form a pattern. Processing efficiency of the laser light can be enhanced by light-absorption of the included light-absorbing material and energy radiation operation.

A display device according to the invention includes a light emitting display device in which a light emitting element sandwiching an organic matter emitting luminescence referred to as electro luminescence (hereinafter also referred to as “EL”) or a medium including a mixture of an organic matter and an inorganic matter between electrodes is connected to a TFT; a liquid crystal display device in which a liquid crystal element having a liquid crystal material is used as a display element; and the like.

A method for forming a pattern according to the invention comprises the steps of: forming a first region having a substance including a light-absorbing material; forming a second region by modifying the surface of the substance by selectively irradiating the substance with laser light having a wavelength which is absorbed by the light-absorbing material; and forming a pattern by discharging a compound including a pattern forming material to the second region.

Another method for forming a pattern according to the invention comprises the steps of: forming a first region having a substance including a light-absorbing material; forming a second region by modifying the surface of the substance by selectively irradiating the substance with laser light having a wavelength which is absorbed by the light-absorbing material; removing the light-absorbing material; and forming a pattern by discharging a compound including a pattern forming material to the second region.

A method for manufacturing a thin film transistor according to the invention comprises the steps of: forming a first region having a substance including a light-absorbing material; forming a second region by modifying the surface of the substance by selectively irradiating the substance with laser light having a wavelength which is absorbed by the light-absorbing material; and forming an electrode layer by discharging a compound including a conductive material to the second region.

Another method for manufacturing a thin film transistor according to the invention comprises the steps of: forming a first region having a substance including a light-absorbing material; forming a second region by modifying the surface of the substance by selectively irradiating the substance with laser light having a wavelength which is absorbed by the light-absorbing material; removing the light-absorbing material; and forming an electrode layer by discharging a compound including a conductive material to the second region.

In the above-mentioned structure, a display device can be manufactured by forming the conductive layer as a gate electrode layer. In addition, the surface of the substance can be modified so that the second region has higher wettability than that of the first region with respect to the compound.

A thin film transistor according the invention comprises an electrode layer provided over an insulating surface having a first region and a second region, wherein the first region and the second region are provided over a substance including a light-absorbing material, the electrode layer is provided in the second region, and the second region has higher wettability than that of the first region with respect to the electrode layer.

A thin film transistor according to the invention comprises an electrode layer provided over an insulating surface having a first region and a second region, wherein the second region is provided over a substance including a light-absorbing material, the electrode layer is provided in the second region, and the second region has higher wettability than that of the first region with respect to the electrode layer.

A display device according to the invention comprises a thin film transistor including a gate electrode layer provided over an insulating surface having a first region and a second region, wherein the first region and the second region are provided over a substance including a light-absorbing material, the gate electrode layer is provided in the second region, and the second region has higher wettability than that of the first region with respect to the gate electrode layer.

A display device according to the invention comprises a thin film transistor including a gate electrode layer provided over an insulating surface having a first region and a second region, wherein the second region is provided over a substance including a light-absorbing material, the gate electrode layer is provided in the second region, and the second region has higher wettability than that of the first region with respect to the gate electrode layer.

A display screen of a television device according to the invention comprises a display device having a thin film transistor including a gate electrode layer provided over an insulating surface having a first region and a second region, wherein the first region and the second region are provided over a substance including a light-absorbing material, the gate electrode layer is provided in the second region, and the second region has higher wettability than that of the first region with respect to the gate electrode layer.

A display screen of a television device according to the invention comprises a display device having a thin film transistor including a gate electrode layer provided over an insulating surface having a first region and a second region, wherein the second region is provided over a substance including a light-absorbing material, the gate electrode layer is provided in the second region, and the second region has higher wettability than that of the first region with respect to the gate electrode layer.

In the above-mentioned structure, the substance including a light-absorbing material may be liquid in which the light-absorbing material is dissolved and mixed into the substance, or the light-absorbing material is dispersed in the substance. Additionally, a pigment can be used as the light-absorbing material, and the substance including a light-absorbing material may be formed so as to include a substance having a fluorocarbon chain which is a substance having fluorine.

According to the invention, a desirable pattern can be formed with preferable controllability; therefore, the loss of a material and the cost can be reduced. Hence, a high-performance and highly reliable display device can be manufactured with a preferable yield.

### BRIEF DESCRIPTION OF THE DRAWINGS

FIGS. 1A to 1E are views describing a certain aspect of the present invention;

FIGS. 2A to 2C are views describing a certain aspect of the invention;

FIGS. 3A to 3C are views describing a method for manufacturing a display device according to a certain aspect of the invention;

FIGS. 4A to 4C are views describing a method for manufacturing a display device according to a certain aspect of the invention;

FIGS. 5A to 5C are views describing a method for manufacturing a display device according to a certain aspect of the invention;

FIGS. 6A to 6C are views describing a method for manufacturing a display device according to a certain aspect of the invention;

FIGS. 7A to 7C are views describing a method for manufacturing a display device according to a certain aspect of the invention;

FIGS. 8A to 8C are views describing a method for manufacturing a display device according to a certain aspect of the invention;

FIGS. 9A and 9B are views describing a method for manufacturing a display device according to a certain aspect of the invention;

FIGS. 10A to 10E are views describing a method for manufacturing a display device according to a certain aspect of the invention;

FIGS. 11A and 11B are views describing a method for manufacturing a display device according to a certain aspect of the invention;

FIGS. 12A to 12C are cross-sectional views of a display device according to a certain aspect of the invention;

FIG. 13 is a view describing a structure of a laser light direct imaging apparatus which is applicable to a certain aspect of the invention;

FIGS. 14A to 14C are top views of a display device according to a certain aspect of the invention;

FIGS. 15A and 15B are top views of a display device according to a certain aspect of the invention;

FIG. 16 is a view describing a method for manufacturing a display device according to a certain aspect of the invention;

FIGS. 17A to 17F are circuit diagrams describing a structure of a pixel which is applicable to an EL display panel according to a certain aspect of the invention;

FIGS. 18A and 18B are top views describing a display panel according to a certain aspect of the invention;

FIG. 19 is a cross-sectional view describing a structure example of an EL display module according to a certain aspect of the invention;

FIGS. 20A and 20B are figures showing electronic devices to which a certain aspect of the invention is applied;

FIGS. 21A to 21D are figures showing electronic devices to which a certain aspect of the invention is applied;

FIG. 22 is a cross-sectional view describing a structure example of an EL display module according to a certain aspect of the invention;

FIG. 23 is an equivalent circuit diagram of an EL display panel which is described in FIG. 24.

FIG. 24 is a top view describing an EL display module according to a certain aspect of the invention;

FIG. 25 is a view describing a circuit structure when a scanning line driver circuit is formed of a TFT in an EL display panel according to a certain aspect of the invention;

FIG. 26 is a diagram describing a circuit structure when a scanning line driver circuit is formed of a TFT in an EL display panel according to a certain aspect of the invention (a shift resistor circuit);

FIG. 27 is a diagram describing a circuit structure when a scanning line driver circuit is formed of a TFT in an EL display panel according to a certain aspect of the invention (a buffer circuit);

FIG. 28 is a figure describing a structure of a droplet discharge device which is applicable to a certain aspect of the invention;

FIG. 29 is a figure describing a droplet discharge injection method which is applicable to a certain aspect of the invention;

FIG. 30 is a cross-sectional view describing a structure example of liquid crystal module according to a certain aspect of the invention;

FIGS. 31A to 31D show patterns manufactured according to a certain aspect of the invention;

FIGS. 32A to 32C show patterns manufactured according to a certain aspect of the invention;

FIG. 33 is a graph showing the relation between scanning rate of laser light which is applied to a certain aspect of the invention and a region which is irradiated with the laser light; and

FIG. 34 is a graph showing the relation between energy density of laser light which is applied to a certain aspect of the invention and a region which is irradiated with the laser light.

### DETAILED DESCRIPTION OF THE INVENTION

### Embodiment Mode 1

Embodiment Mode of the present invention will be described below in detail with reference to the accompanying drawings. However, the invention is not limited to the following description and it is easily understood that various changes and modifications will be apparent to those skilled in the art, unless such changes and modifications depart from content and the scope of the invention. Therefore, the invention is not interpreted with limiting to the description in embodiment modes shown hereinafter. Note that, in the structure of the invention described hereinafter, the same reference numerals denote the same parts or parts having the same function in different drawings and the explanation will not be repeated.

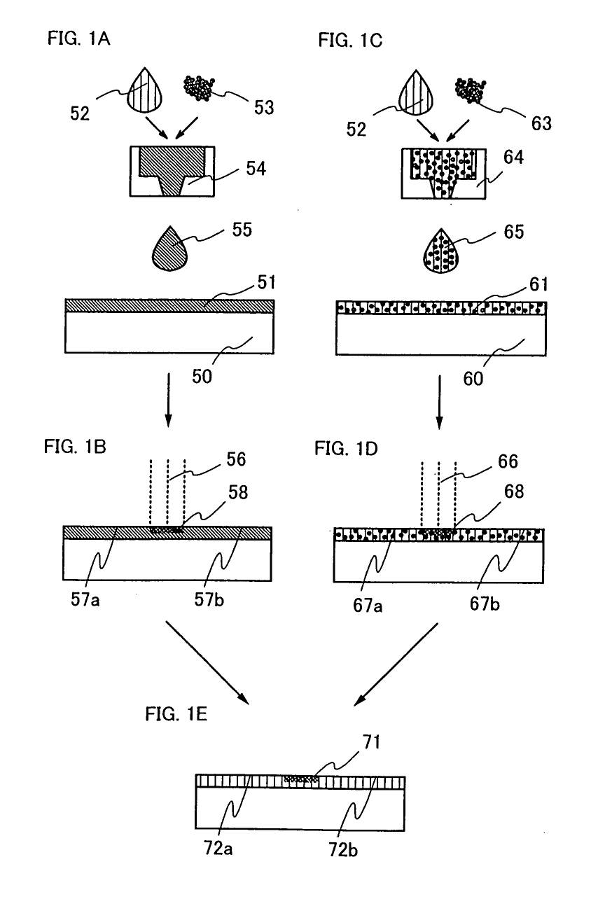

An embodiment mode according to the invention is described with reference to FIGS. 1A to 1E. Two examples are shown in FIGS. 1A to 1E. One of them is an example which reaches FIG. 1E through FIGS. 1A and 1B, and the other is an example which reaches FIG. 1E through FIGS. 1C and 1D.

One feature of the invention is that at least one or more of patterns required to manufacture a display panel, such as a wiring layer, a conductive layer for forming an electrode, or a mask layer for forming a predetermined pattern is/are formed by a method capable of selectively forming a pattern to manufacture a display device. A droplet discharge (apply) method (also referred to as an ink-jet method, depending on its mode) that can form a conductive layer, an insulating layer, or the like into a predetermined pattern by selectively discharging (applying) a droplet of a compound mixed for a particular purpose is employed as the method capable of selectively forming a pattern. In addition, a method capable of transferring or imaging a pattern, for example, various printing methods (a method for forming a pattern, such as screen (mimeograph) printing, offset (lithography) printing, relief printing or gravure (copperplate printing) or the like can also be employed.

In this embodiment mode, a method for forming a pattern by discharging (applying) a compound including a fluid pattern as a droplet is used. A pattern is formed by discharging a droplet including a pattern forming material to a pattern formation region, and by performing baking, drying, and the like to fix. According to the invention, pretreatment is performed on a pattern formation region.

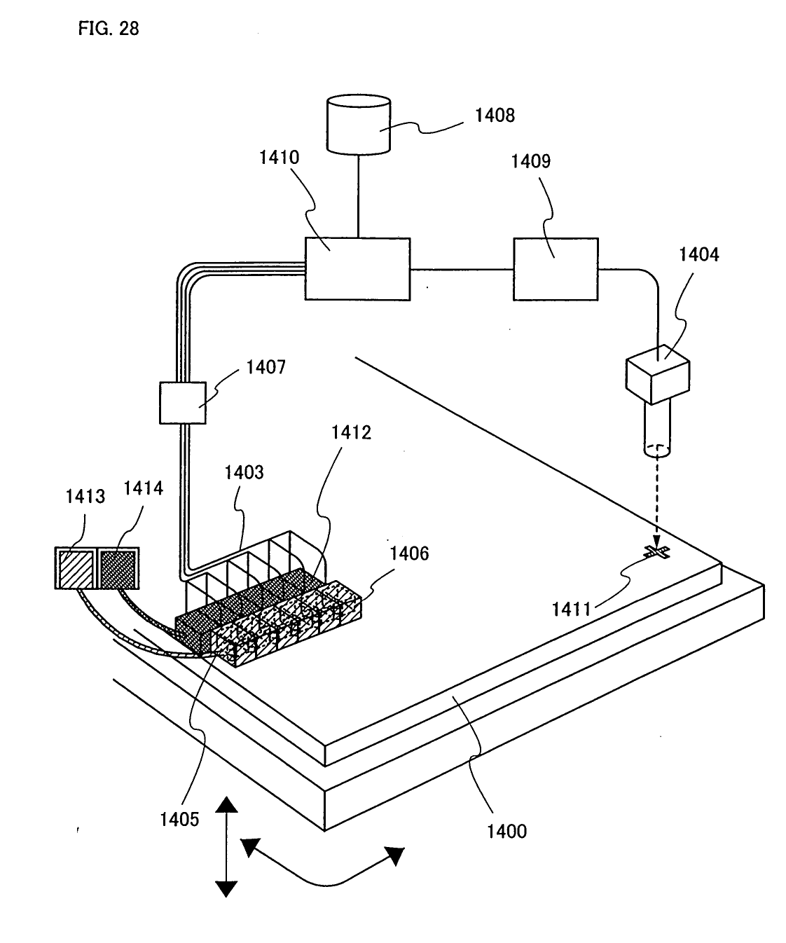

One mode of a droplet discharge apparatus used for forming a pattern is shown in FIG. 28. Each of head 1405 and 1412 of a droplet discharge means 1403 is connected to a control means 1407, and is controlled by a computer 1410, so that a preprogrammed pattern can be formed. The formation position may be determined based on a marker 1411 that is formed over a substrate 1400, for example. Alternatively, a reference point can be fixed based on an edge of the substrate 1400. The reference point is detected by an imaging means 1404 such as a CCD, and changed into a digital signal at an image processing means 1409. Then, the digital signal is recognized by the computer 1410, and a control signal is generated and is transmitted to the control means 1407. Naturally, information on a pattern to be formed over the substrate 1400 is stored in a storage medium 1408, and a control signal is transmitted to the control means 1407 based on the information, so that each head 1405 and 1412 of the droplet discharge means 1403 can be individually controlled. Each head 1405 and 1412 is supplied with a material to be discharged from material supply sources 1413 and 1414 through a pipe.

The head 1405 has an inside structure which has a space filled with a liquid material and a nozzle which is a discharge opening as shown by a dotted line 1406. Although it is not shown, the head 1412 has a similar inside structure to the head 1405. The sizes of the heads 1405 and 1412 are different each other, and different materials can be simultaneously formed to have different widths. A conductive material, an organic material, an inorganic material, and the like can be discharged from one head and. When a droplet is drawn over a wide area such as an insulating film, one material is simultaneously discharged from a plurality of nozzles to improve a throughput, and thus, drawing can be performed. When a large-sized substrate is used, the heads 1405 and 1412 can freely scan over the substrate in a direction indicated by an arrow, and a region to be drawn can be freely set. Thus, a plurality of the same patterns can be formed over one substrate.

In a pattern forming method of a conductive layer or the like with the use of a droplet discharge method, a pattern is formed as follows. A pattern forming material which is processed in a particulate shape is discharged, and welded or joined by welding by performing baking to cure the pattern forming material. Accordingly, a pattern which is formed by a sputtering method or the like often shows a columnar shape while the pattern formed by a method of the present invention often shows a polycrystalline state having a lot of grain boundaries.

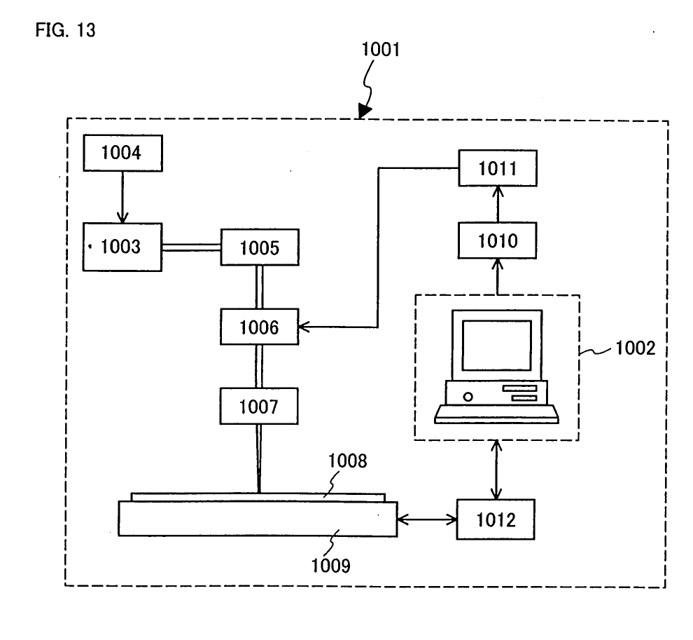

A laser light direct imaging apparatus for imaging laser light (also, referred to as a laser beam) on a processing region is described with reference to FIG. 13. In this embodiment mode, a laser light direct imaging apparatus is used since a region which is to be irradiated with laser light is not selected through a mask or the like, but it is processed by selecting a processing region and directly irradiating the region. As shown in FIG. 13, a laser light direct imaging apparatus 1001 comprises: a personal computer (hereinafter, referred to as a “PC”) 1002 which performs various control at the time of radiating laser light; a laser oscillator 1003 which outputs laser light; a power source 1004 of the laser oscillator 1003; an optical system (an ND filter) 1005 for attenuating laser light; an acoustooptical modulator (AOM) 1006 for modulating the intensity of laser light; an optical system 1007 including a lens for expanding or scaling the cross-section of laser light, a mirror for modifying a light path and the like; a substrate moving mechanism 1009 having an X stage and a Y stage; a D/A converter 1010 which converts control data output from a PC from digital into analog, a driver 1011 which controls the acoustooptical modulator 1006 according to an analog voltage output from the D/A converter 1010; and a driver 1012 which outputs a drive signal for driving the substrate moving mechanism 1009.

As the laser oscillator 1003, a laser oscillator which can oscillate an ultraviolet light, visible light, or infrared light. As the laser oscillator, an excimer laser oscillator of KrF, ArF, XeCl, Xe, or the like; a gas laser oscillator of He, He—Cd, Ar, He—Ne, HF, or the like; a solid laser oscillator using a crystal such as YAG, GdVO₄, YVO₄, YLF, or YAlO₃ doped with Cr, Nd, Er, Ho, Ce, Co, Ti or Tm; or a semiconductor laser oscillator of GaN, GaAs, GaAlAs, InGaAsP, or the like can be used. As a solid laser oscillator, it is preferable to apply from the first higher harmonics to the fifth higher harmonics of the fundamental wave.

Then, modification treatment of a substance (surface) using a laser light direct imaging apparatus will be described. When a substrate 1008 is mounted on the substrate moving mechanism 1009, the PC 1002 detects the position of a marker on the substrate using a camera not shown in the figure. Then, movement data for moving the substrate moving mechanism 1009 is generated based on the detected position data of the marker on the substrate and preprogrammed pattern data by the PC 1002. The PC 1002 controls the amount of output light of the acoustooptical modulator 1006 through the driver 1011. Accordingly, after laser light output from the laser oscillator 1003 is attenuated by the optical system 1005, the amount of light is controlled by the acoustooptical modulator 1006 so as to be the predetermined amount of light. The light path and the shape of laser light (a beam spot) output from the acoustooptical modulator 1006 is modified through the optical system 1007, and condensed with the lens. Afterwards, an object to be processed formed over the substrate is irradiated with the laser light to performed modification treatment. At this time, the substrate moving mechanism 1009 is moved and controlled in the X direction and Y direction based on the movement data generated by the PC 1002. As a result, a predetermined spot is irradiated with laser light, thereby performing modification treatment on the object to be processed.

As a result, as shown in FIG. 1B, a region irradiated with the laser light over the object to be processed is modified and wettability is enhanced. Accordingly, the wettability in a region 58 is higher compared with regions 57a and 57b; therefore, regions having different wettability, namely, the high-wettability region 58 where wettability is comparatively high and the low-wettability regions 57a and 57b where wettability is low are formed. A part of the energy of the laser light is converted into heat due to a material for the object to be processed and reacts with a part of the object to be processed. Therefore, there is a case when the width of the region 58 of the processed object is slightly wider than that of the laser light. The diameter of the laser light can be condensed to be narrower with the use of laser light having a shorter wavelength; therefore, it is preferable to radiate laser light having a short wavelength to form a processing region having a minute width.

A spot shape of the laser light on the film surface is processed by an optical system to be a dotted-shape, a circular shape, an elliptical shape, a rectangular shape, or a linear shape (precisely, an elongated rectangular shape).

Although an example of the apparatus in which laser light is radiated from the surface side of a substrate to expose the substrate to light is shown in FIG. 13, a laser light direct imaging apparatus in which an optical system or a substrate moving mechanism is appropriately changed and laser light is radiated from the back side of a substrate to expose the substrate to light may be also used.

Although the substrate is selectively irradiated with the laser light by moving the substrate, the laser light can be radiated by moving the laser light in the X-Y axis direction without being limited thereto. In this case, it is preferable to use a polygon mirror or a galvanometer mirror for the optical system 1007.

According to the invention, as shown in FIGS. 1A to 1E, irradiation treatment with the use of the laser light is performed on a pattern formation region and a region adjacent thereto as pretreatment to perform treatment for selectively modifying the surface. A compound including a pattern material is attached to the modified surface to form the pattern. In this embodiment mode, the laser light is radiated so that the wettability of the irradiated region is modified. Accordingly, the pattern formation region and the region adjacent thereto having different wettability with respect to a pattern forming material are formed. The difference in the wettability is the relative relation between the both regions. It is permissible when there is a difference in wettability with the pattern forming material between a pattern formation region and a non-pattern formation region adjacent thereto. The regions having different wettability mean regions having different angles of contact. A region having a large angle of contact of a forming material means a region having low wettability (hereinafter, also referred to as a “low-wettability region”), and a region having a small angle of contact of a forming material means a region having high wettability (hereinafter, also referred to as a “high-wettability region”). This is because when an angle of contact is large, a liquid compound having fluidity does not diffuse on the surface of a region and the compound is repelled; therefore, the surface is not wetted; and when an angle of contact is small, a compound having fluidity diffuses over the surface, and the surface is wetted. In the invention, the difference in the angles of contact between the regions having different wettability is 30° C. or more, preferably, 40° C. or more.

In this embodiment mode, irradiation treatment with the use of a laser light is performed to form regions having different wettability. A substance is formed over a pattern formation region and a region adjacent thereto, and treatment for selectively enhancing wettability and treatment for selectively decreasing wettability are performed with the use of the laser light. In this embodiment mode, a substance having low wettability is formed over a pattern formation region and a region adjacent thereto, and laser light having a degree of decomposing the substance having low wettability is radiated to decompose and remove the substance having low wettability in a processing region; therefore, wettability in the processing region is enhanced resulting in forming a high-wettability region. A substance having low wettability may be a substance including a material having an effect of decreasing the wettability. The material decreasing wettability is decomposed and destroyed by laser irradiation treatment to neutralize the effect of decreasing wettability. It is necessary to use laser light having a wavelength which is absorbed by the substance, having low wettability, to be used. However, light having large energy of 300 nm or less such as an ultraviolet light is required depending on a substance; therefore, the range of choice is narrowed. Additionally, it is also required to perform irradiation plural times to perform sufficient treatment; therefore, the cost or time necessary for an apparatus or process is increased causing decrease in productivity.

Hence, according to the invention, a light-absorbing material having an absorbing region in a wavelength region of laser light is added to a substance to be processed to improve efficiency of laser irradiation treatment. The light-absorbing material having an absorbing region in the wavelength region of the laser light absorbs the irradiated laser light and emits (radiates) the laser light to its circumference. The emitted energy reacts with a peripheral substance. As a result, the substance property is changed and modified. According to the invention, the range of choice for laser light is widened since a light-absorbing material may be selected in accordance with laser light. In addition, treatment can be sufficiently performed even when laser light has lower energy itself since irradiation efficiency of the laser light can also be enhanced. Hence, an apparatus or process is simplified and the cost or time is reduced, which leads to enhancing productivity.

In this embodiment mode, a light-absorbing material 53 or a light-absorbing material 63 is added to a substance 52 having low wettability. The substance having low wettability is mixed into a solvent or the like to be in liquid form since an applying method which uses the substance having low wettability in liquid form is employed. However, the forming method is not limited to this embodiment mode since a substance may be attached to a formation region and a region adjacent thereto. For example, the substance having low wettability can be formed by a sol-gel method such as a dip coating method, a spin coating method, a droplet discharge method, or an ion plating method, an ion beam method, a CVD method, a sputtering method, an RF magnetron sputtering method, or a plasma spraying method. When forming by an application method such as a dip coating method or a spin coating method, and when a solvent should be removed, baking or drying may be performed. When a method of forming a pattern directly over a formation region and a region adjacent thereto such as a droplet discharge method is used, the cost can be curtailed since material usability is enhanced.

When a substance soluble in the substance 52 having low wettability such as a colorant is used as the light-absorbing material, the light-absorbing material added in the substance 52 having low wettability becomes a compound having low wettability in liquid form by being dissolved into the substance 52 having low wettability as shown in FIG. 1A. The compound is discharged over a substrate 50 from a discharging device 54 as a droplet 55 to form a compound 51 having low wettbaility.

Only a pattern formation region of the compound 51 having low wettability is irradiated with laser light 56 with a laser irradiation device. The light-absorbing material included in the compound 51 having low wettability has an absorption region in the wavelength of the laser light; therefore, the light-absorbing material absorbs the radiated laser light to emit the energy. The substance having low wettability is decomposed and destroyed by the emitted energy to enhance the wettability in the processing region. Accordingly, a high-wettability region 58 is formed, and the formation region and the region adjacent thereto are formed to have different wettability. Therefore, wettability is comparatively low in a non-processing region; therefore, low-wettability regions 57a and 57b are formed.

After forming the regions having different wettability, the light-absorbing material included in the compound having low wettability may be cleaned with alcohol or water and removed. In this case, in order to remove only the light-absorbing material, it is necessary to select a solvent having high selective ratio so that the substance 52 having low wettability is not dissolved. In this embodiment mode, cleaning is performed with a solvent which dissolves the light-absorbing material 53 and the light-absorbing material 53 is removed, thereby forming a high-wettability region 71, low-wettability regions 72a and 72b (see FIG. 1E).

FIGS. 1A and 1B show the case where the light-absorbing material is soluble in the substance 52 having low wettability, and the case where a light-absorbing material such as a colorant which is insoluble in the substance is shown in FIGS. 1C and 1D. The light-absorbing material 63 is insoluble in the substance 52 having low wettability. Therefore, the light-absorbing substance 63 is dispersed and included in the substance 52 having low wettability as a particle. A component having low wettability in which the light-absorbing material is dispersed and included as a particle is discharged over a substrate 60 from a discharging device as a droplet 65 to form a compound 61 having low wettability. It is necessary to use a particle which is smaller than a processing region in this case. This is because the minimum value of the processing region is determined by the size of the particle since energy emitted from the particle affects a peripheral substance.

Only a pattern formation region is irradiated with laser light 66 by a laser irradiation device to form a high-wettability region 68, and low-wettability regions 67a and 67b (see FIG. 1D). Then, the light-absorbing material 63 is cleaned by a solvent which dissolves the light-absorbing material 63 and removed to form the high-wettability region 71 and the low-wettability regions 72a and 72b (see FIG. 1E).

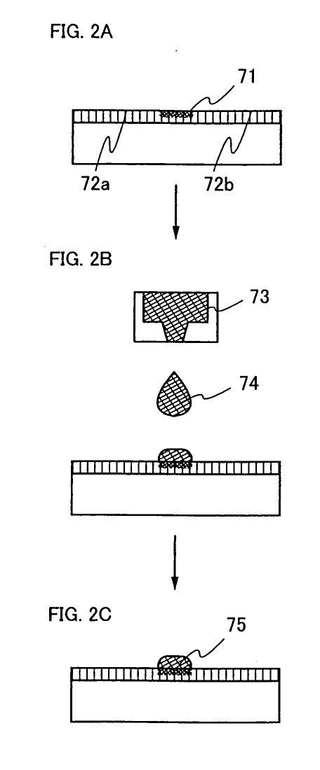

Afterwards, a droplet 74 including the pattern forming material is discharged from a nozzle of a droplet discharge device 73 to the high-wettability region 71 which is a formation region. The discharged droplet 74 is formed in the high-wettability region 71 not in the low-wettability regions 72a and 72b (see FIG. 2B). Even when a discharge opening of the nozzle from which the droplet is discharged is larger than the desirable size, the droplet is attached only to the formation region to form a desired pattern 75 by performing treatment for enhancing wettability on the formation region (see FIG. 2C). This is because the formation region and a region adjacent thereto have different wettability; therefore, the droplet is repelled in the peripheral low-wettability region to remain in a formation region having higher wettability. In other words, the compound including a pattern forming material is discharged only to the high-wettability region and a droplet is repelled by the low-wettability region surrounding a periphery of the high-wettability region. Therefore, the boundary between the high-wettability region and the low-wettability region functions as a partition wall (a bank). A pattern can be formed to have a desired shape since even the pattern forming material having fluidity can remain in the high-wettability region.

According to the invention, when a minute pattern of, for example, a conductive layer, or the like is formed, a droplet is not diffused over a formation region even when a discharge opening of a droplet is large somewhat, therefore, a pattern can be made narrower. Additionally, a film thickness of the wiring can be controlled by controlling the amount of the droplet. As in this embodiment mode, when the surface of the substance is modified by laser light irradiation, a minute process can be performed by being irradiated with the laser light; therefore, a minute wiring, electrode, or the like can be formed with preferable controllability. In addition, by combining a droplet discharge method, the loss of a material can be prevented compared with entire application formation by a spin coating method or the like; therefore, the cost can be reduced.

In this embodiment mode, the compound having low wettability is formed as pretreatment. The film could be extremely thin depending on the formation condition. Accordingly, the compound does not necessarily keep the form as a film.

Treatment for enhancing wettability means to make the strength of holding a droplet to be discharged over a region (also referred to as “adherence strength” or “fixing strength”) stronger than that in a surrounding region. Modifying a region by irradiation treatment with the use of laser light to enhance adhesiveness with a droplet has the same meaning as the process for enhancing wettability. Only a surface which is in contact with and holds a droplet may have the wettability, and the entire film thickness direction does not necessarily have the similar properties.

The substance which changes wettability formed as pretreatment after forming the pattern may be left, or an unnecessary portion may be removed after forming the pattern. The pattern may be used as a mask, and ashing using oxygen or the like, etching, or the like may be used for the removal.

As an example of the compound of the solution for forming the low-wettability region, a silane coupling agent expressed in a chemical formula of Rₙ—Si—X₍₄₋ₙ₎ (n=1, 2, 3) is used. Here, R denotes a substance which contains a comparatively inactive group such as an alkyl group. Further, includes a hydrolysable group which can be bonded by the condensation with a hydroxyl group or absorptive water on a surface such as halogen, a methoxy group, an ethoxy group, or an acetoxy group.

By using fluorine-based silane coupling agent (fluoroalkylsilane (hereinafter referred to as FAS)) having a fluoroalkyl group for R as a representative example of the silane coupling agent, the wettability can be lowered. R of FAS has a structure which is expressed in (CF₃) (CF₂)ₓ(CH₂)_{y} (x: an integer from 0 to 10, y: an integer from 0 to 4). In the case where a plurality of R or X are bonded to Si, R or X may all be the same or different. Fluoroalkylsilane such as heptadecafluorotetrahydrodecyltriethoxysilane, heptadecafluorotetrahydrodecyltrichlorosilane, tridecafluorotetrahydrooctyltrichlorosilane, trifluoropropyltrimethoxysilane can be given as FAS.

As the solvent of a solution for forming the low-wettability region, a solvent which forms a low-wettability region such as a hydrocarbon-based solvent, tetrahydrofuran, or the like, namely, n-pentane, n-hexane, n-heptane, n-octane, n-decane, dicyclopentane, benzene, toluene, xylene, durene, indene, tetrahydronaphthalene, decahydronaphthalene, squalene, or the like is used.

As an example of the compound of the solvent forming the low-wettability region, a substance having a fluorocarbon chain (a fluorine resin) can be used. As the fluorine resin, polytetrafluoroethylene (PTFE; a polytetrafluoroethylene resin), perfluoroalkoxyalkane (PFA; a tetrafluoroethylene perfluoroalkylvinylether copolymer resin), perfluoroethylene propylene copolymer (PFEP; a tetrafluoroethylene hexafluoropropylene copolymer resin), ethylene-tetrafluoroethylene copolymer (ETFE; a tetrafluoroethylene-ethylene copolymer resin), polyvinylidene fluoride (PVDF; a polyvinylidene fluoride resin), polychlorotrifluoroethylene (PCTFE; a polytrifluorochloroethylene resin), ethylene-chlorotrifluoroethylene copolymer (ECTFE; a polytrifluorochloroethylene-ethylene copolymer resin), polytetrafluoroethylene-perfluorodioxol copolymer (TFE/PDD), polyvinylfluoride (PVF; a vinyl fluoride resin), or the like can be used.

In addition, an organic material which does not form a low-wettability region (in other words, forms a high-wettability region) may be used to form a low wetttability region by performing treatment with the use of CF₄ plasma or the like later. For example, a material in which a soluble resin such as polyvinyl alcohol (PVA) is mixed into a solvent such as H₂O can be used. In addition, PVA may be mixed with another soluble resin may be also used. An organic material (an organic resin material) (polyimide, acrylic), a material in which a skeleton is configured by the bond of silicon (Si) and oxygen (O), and which includes at least hydrogen as a substituent, or at least one of fluoride, an alkyl group and aromatic hydrocarbon as a substituent may be used. Further, even when a material having a low-wettability region is used, wettability can be further decreased by performing plasma treatment or the like.

A base film may be formed to improve adhesiveness of the pattern and the formation region. For example, when a conductive material containing silver is applied to a substrate to form a silver wiring, a titanium oxide film may be formed over the substrate as a conductive film to improve adhesiveness. The titanium oxide film has preferable adhesiveness with the conductive material containing silver to be formed or the like, thereby enhancing reliability.

As the light-absorbing material, an organic material, an inorganic material, a substance including an inorganic material and an organic material, or the like can be used, and a light-absorbing material having an absorbing region in a wavelength of laser light to be used may be selected. It may be a conductive material such as metal or an insulating material such as an organic resin. As an inorganic material, iron, gold, copper, silicon or germanium, as an organic material, plastic such as polyimide or acrylic, a pigment, or the like can be used. For example, as a pigment corresponding to laser having the wavelength of 532 nm, rhodamine B, eosine Y, methyl orange, rose bengal, or the like, and as a pigment corresponding to laser having the wavelength of 405 nm, coumarins (coumarin 6H, coumarin 102, coumarin 152, coumarin 153, or the like) can be used, respectively. As a pigment, carbon black, a black resin of a pigment, or the like can also be used.

A pattern can be formed to have a desired shape by performing pretreatment on a region where a pattern is to be formed to improve adhesiveness with the pattern compared with a surrounding region. In addition, a minute pattern can be freely designed by minute processing with laser light irradiation. According to the invention, a desired pattern can be formed with preferable controllability; therefore, the loss of a material and the cost can be reduced. Hence, a high-performance and highly reliability light emitting display device can be manufactured with a preferable yield.

### Embodiment Mode 2

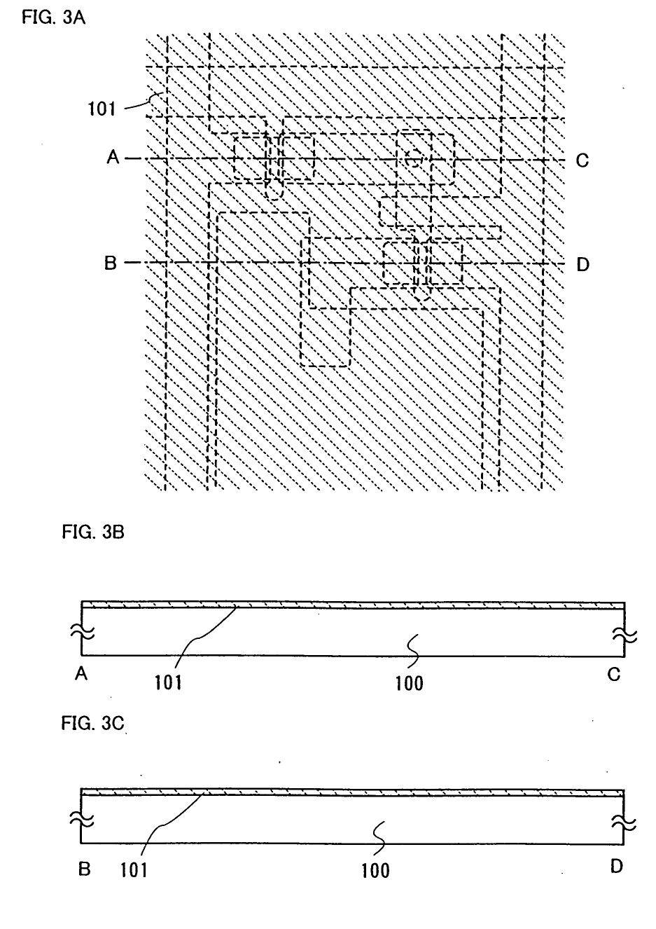

Embodiment mode according to the present invention is described with reference to FIGS. 3A to 3C, FIGS. 4A to 4C, FIGS. 5A to 5C, FIGS. 6A to 6C, FIGS. 7A to 7C, FIGS. 8A to 8C, FIGS. 9A and 9B, FIGS. 14A to 14C, and FIGS. 15A and 15B. In more detail, a method for manufacturing a display device having a channel etch type thin film transistor to which the invention is applied is described. FIGS. A in FIGS. 3 to 8 show top views of display device pixel portions, FIGS. B in FIGS. 3 to 8 show cross-sectional views taken along the lines of A-C in FIGS. A in FIGS. 3 to 8, and FIGS. C in FIGS. 3 to 8 show cross-sectional views taken along the lines of B-D in FIGS. A in FIGS. 3 to 8.

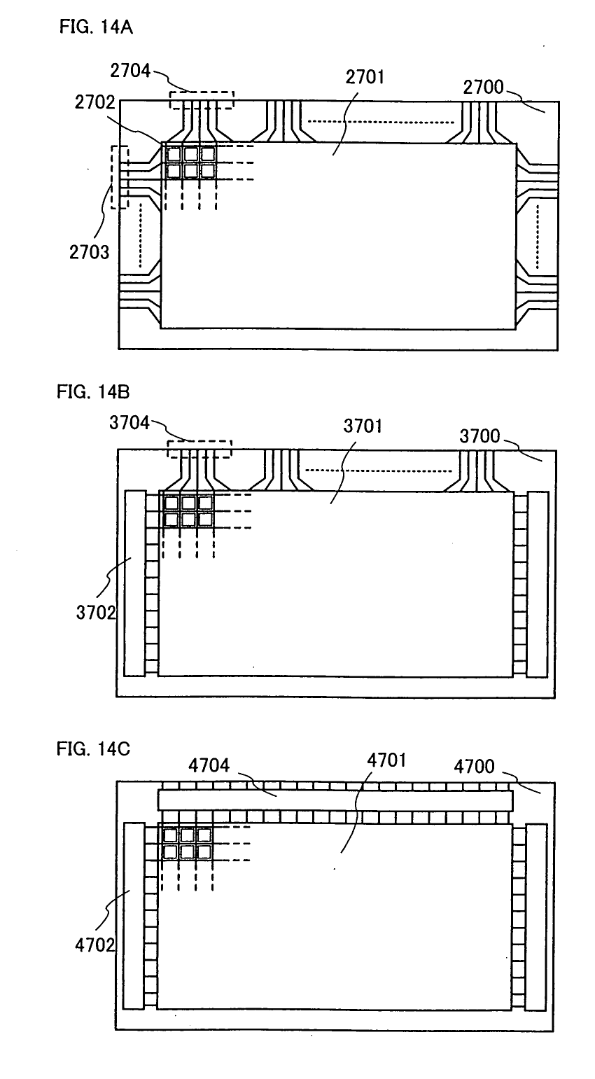

FIG. 14A is a top view showing a structure of a display panel according to the invention. A pixel portion 2701 in which pixels 2702 are arranged in a matrix, a scanning line input terminal 2703, and a signal line input terminal 2704 are formed over a substrate 2700 having an insulating surface. The number of pixels may be determined in accordance with various standards. The number of pixels of XGA may be 1024×768×3 (RGB), that of UXGA may be 1600×1200×3 (RGB), and that of a full-spec high vision may be 1920×1080×3 (RGB).

The pixels 2702 are arranged in a matrix by intersecting a scanning line extended from the scanning line input terminal 2703 with a signal line extended from the signal line input terminal 2704. Each of pixels 2702 is provided with a switching element and a pixel electrode connected thereto. A typical example of the switching element is a TFT. The gate electrode of the TFT is connected to a scanning line, and the source or drain thereof is connected to a signal line, which enables each pixel to be controlled independently by a signal input from outside.

The TFT includes a semiconductor layer, a gate insulating layer, and a gate electrode layer as its main components. A wiring layer connected to a source-drain region formed in the semiconductor layer is also included in the TFT. A top gate type in which a semiconductor layer, a gate insulating layer, and a gate electrode layer are arranged from the substrate side, a bottom gate type in which a gate electrode layer, a gate insulating layer, and a semiconductor layer are arranged from the substrate side, and the like are known as a typical structure of a TFT. However, any one of the structures may be employed in the invention.

An amorphous semiconductor (hereinafter also refereed to as a “AS”) manufactured by a vapor phase growth method or a sputtering method using a semiconductor material gas typified by silane or germane; a polycrystalline semiconductor that is formed by crystallizing the amorphous semiconductor by utilizing light energy or thermal energy; a semi-amorphous (also referred to as microcrystallite or microcrystal) semiconductor (hereinafter also referred to as a “SAS”); or the like can be used as a material for forming the semiconductor layer.

The SAS means a semiconductor having an intermediate structure between an amorphous structure and a crystalline structure (including a single crystal and a polycrystal) and having a third state which is stable in terms of free energy, and includes a crystalline region having short-range order and lattice distortion. A crystalline region of from 0.5 nm to 20 nm can be observed in at least a part of a region in the film. When silicon is contained as the main component, a Raman spectrum is shifted to a lower frequency side than 520 cm⁻¹. A diffraction peak of (111) or (220) to be caused by a crystal lattice of silicon is observed in X-ray diffraction. Hydrogen or halogen of at least 1 atomic % or more is contained to terminate a dangling bond. The SAS is formed by performing glow discharge decomposition (plasma CVD) on a silicide gas. SiH₄ is given as a typical silicide gas. In addition, Si₂H₆, SiH₂Cl₂, SiHCl₃, SiC₄, SiF₄, or the like can also be used as the silicide gas. Further, F₂ or GeF₄ may be mixed. This silicide gas may be diluted with H₂ or H₂ and one or more rare gas elements of He, Ar, Kr, and Ne. A dilution ratio ranges from 2 times to 1000 times. A pressure ranges approximately from 0.1 Pa to 133 Pa, and a power frequency ranges from 1 MHz to 120 MHz, preferably from 13 MHz to 60 MHz. A substrate heating temperature may be 300° C. or less, and the film can also be formed at temperatures of from 100° C. to 200° C. It is desirable that an atmospheric constituent impurity such as oxygen, nitrogen, or carbon is 1×1020 atoms/cm⁻³ or less as an impurity element in the film; specifically, an oxygen concentration is 5×10¹⁹ atoms/cm⁻³ or less, preferably 1×10¹⁹ atomS/cm⁻³ or less. A preferable SAS can be obtained by further promoting lattice distortion by adding a rare gas element such as helium, argon, krypton or neon to enhance stability. Additionally, a SAS layer including a hydrogen-based gas may be laminated over a SAS layer including a fluorine-based gas.

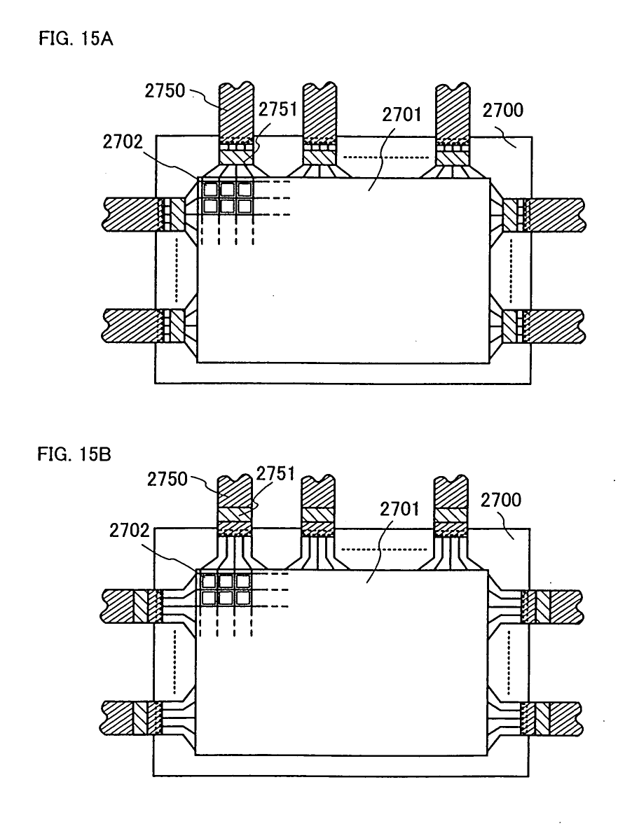

FIG. 14A shows a structure of a display panel that controls a signal to be input to a scanning line and a signal line by an external driver circuit. Furthermore, a driver IC 2751 may be mounted on a substrate 2700 by COG (Chip on Glass) method as shown in FIG. 15A. As another embodiment mode, a TAB (Tape Automated Bonding) method as shown in FIG. 15B may be also used. The driver IC may be formed over a single crystal semiconductor substrate or be a circuit formed with a TFT over a glass substrate. In FIGS. 15A and 15B, driver ICs 2751 are connected to FPCs (Flexible Printed Circuit) 2750.

When a TFT provided in a pixel is formed of a SAS, a scanning line driver circuit 3702 may be integrally formed over a substrate 3700 as shown in FIG. 14B. In FIG. 14B, a pixel portion 3701 is controlled by an external driver circuit which is connected to a signal line input terminal 3704 in the same manner as in FIG. 14A. When a TFT provided in a pixel is formed of a polycrystalline (microcrystallite) semiconductor, a single crystal semiconductor or the like having high mobility, a pixel portion 4701, a scanning line driver circuit 4702 and a signal line driver circuit 4704 can be integrally formed over a substrate 4700 in FIG. 14C.

A glass substrate formed of a barium borosilicate glass, an alumino borosilicate glass or the like, a quartz substrate, a silicon substrate, a metal substrate, a stainless steel substrate or a plastic substrate which can withstand the process temperature of the manufacturing process is used for a substrate 100. A CMP method or the like may be used to polish the surface of the substrate 100 so that it is planarized. In addition, an insulating layer may be formed over the substrate 100. The insulating layer is formed of a single layer or a laminated layer formed of an oxide material or nitride material including silicon by a known method such as a CVD method, a plasma CVD method, a sputtering method, a spin coating method. The insulating layer is not necessarily formed, however, it has an effect of blocking a contaminated substance from the substrate 100. When a base layer is formed to prevent contamination from a glass substrate, a plurality of regions having different wettability (a high-wettability region and a low-wettability region) are formed thereover.

As pretreatment, a pattern formation region is modified to have different wettability with respect to a region adjacent thereto. In this embodiment mode, a substance having low wettability is formed, and the wettability is selectively changed by irradiation treatment using laser light to form a high-wettability region and a low-wettability region. The difference in wettability can be confirmed by angles of contact and it is preferably 40° C. or more. In the invention, a light-absorbing material having an absorption region in a wavelength of laser light to be irradiated is added (mixed) in a processing object to improve irradiation treatment efficiency of laser light.

In this embodiment mode, a pigment is used as the light-absorbing material. A compound 101 having low wettability formed of a low wettability substance and a pigment is formed over the substrate 100 (see FIGS. 3A to 3C).

As an example of the compound of a solution for forming the low-wettability region, a silane coupling agent expressed in a chemical formula of Rₙ—Si—X₍₄₋ₙ₎ (n=1, 2, 3) is used. Here, R denotes a substance which contains a comparatively inactive group such as an alkyl group. Further, X includes a hydrolyzable group which can be bonded by the condensation with a hydroxyl group or absorptive water on a surface such as halogen, a methoxy group, an ethoxy group, or an acetoxy group.

By using fluorine-based silane coupling agent (fluoroalkyl silane (hereinafter referred to as FAS)) having a fluoroalkyl group for R as a representative example of the silane coupling agent, the wettability can be lowered. R of FAS has a structure which expressed in (CF₃)(CF₂)ₓ(CH₂)_{y} (x: an integer from 0 to 10, y: an integer from 0 to 4). In the case where a plurality of R or X are bonded to Si, R or X may all be the same or different. Fluoroalkylsilane such as heptadecafluorotetrahydrodecyltriethoxysilane, heptadecafluorotetrahydrodecyltrichlorosilane, tridecafluorotetrahydrooctyltrichlorosilane, trifluoropropyltrimethoxysilane can be used as FAS.

As the solvent of a solution for forming the low-wettability region, a solvent which forms a low-wettability region such as a hydrocarbon-based solvent, tetrahydrofuran, or the like, namely, n-pentane, n-hexane, n-heptane, n-octane, n-decane, dicyclopentane, benzene, toluene, xylene, durene, indene, tetrahydronaphthalene, decahydronaphthalene, squalene, or the like is used.

As an example of the compound of the solvent forming the low-wettability region, a material having a fluorocarbon chain (a fluorine resin) can be used. As the fluorine resin, polytetrafluoroethylene (PTFE; a polytetrafluoroethylene resin), perfluoroalkoxyalkane (PFA; a tetrafluoroethylene perfluoroalkylvinylether copolymer resin), perfluoroethylene propylene copolymer (PFEP; a tetrafluoroethylene hexafluoropropylene copolymer resin), ethylene-tetrafluoroethylene copolymer (ETFE; a tetrafluoroethylene-ethylene copolymer resin), polyvinylidene fluoride (PVDF; a polyvinylidene fluoride resin), polychlorotrifluoroethylene (PCTFE; a polytrifluorochloroethylene resin), ethylene-chlorotrifluoroethylene copolymer (ECTFE; a polytrifluorochloroethylene-ethylene copolymer resin), polytetrafluoroethylene-perfluorodioxol copolymer (TFE/PDD), polyvinylfluoride (PVF; a vinyl fluoride resin) or the like can be used.

In addition, an organic material which does not form a low-wettability region (in other words, forms a high-wettability region) may be used to form a low wetttability region by performing treatment with the use of CF₄ plasma or the like later. For example, a material in which a soluble resin such as polyvinyl alcohol (PVA) is mixed into a solvent such as H₂O can be used. In addition, PVA may be mixed with another soluble resin may be also used. An organic material (an organic resin material) (polyimide, acrylic), a material in which a skeleton is configured by the bond of silicon (Si) and oxygen (O), and which includes at least hydrogen as a substituent, or at least one of fluoride, an alkyl group, and aromatic hydrocarbon as a substituent may be used. Further, even when a material having a low-wettability region is used, wettability can be further decreased by performing plasma treatment or the like.

In this embodiment mode, FAS is used as the low wettability substance, and a rhodamine B which is a pigment is used as the light-absorbing material. This low wettability substance is used for a compound including a conductive material constituting a gate electrode layer to be formed in a later step. In this embodiment mode, laser light having the wavelength of 532 nm is used; therefore, a rhodamine B which absorbs the wavelength region is selected. A light-absorbing material may be appropriately selected in accordance with the wavelength of laser light. In this embodiment mode, although application is performed over the entire surface with the use of a spin coating method, the light-absorbing material may be selectively formed in a pattern formation region and a region adjacent thereto. In this case, material usability is enhanced since a material is prevented from being wasted.

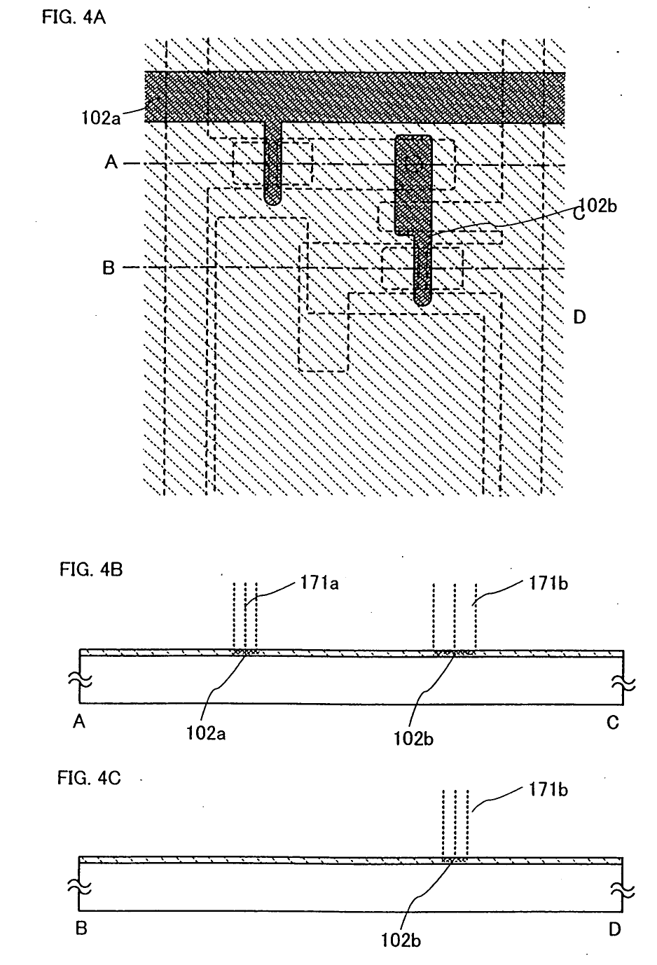

Then, a region where a gate electrode layer is to be formed is irradiated with laser light 171a and 171b by a laser irradiation device to decompose the substance having low wettability in an irradiation region, thereby enhancing wettability. The light-absorbing material mixed into the compound having low wettablity absorbs the laser light and emits the energy. Thus, processing efficiency of laser light irradiation is enhanced. According to the laser light irradiation treatment, the irradiated region becomes high-wettability regions 102a and 102b which have comparatively high wettability compared with a surrounding region thereof (see FIGS. 4A to 4C). According to the invention, the range of choices for laser light can be widened since a light-absorbing material may be selected in accordance with laser light. In addition, treatment can be sufficiently performed even when laser light has lower energy itself since irradiation efficiency of laser light can also be enhanced. Hence, a device or process is simplified and the cost or time is reduced, thereby also enhancing productivity.

After forming regions having different wettability, the light-absorbing material included in the compound having low wettability may be cleaned with alcohol, water, or the like and removed. Since only the light-absorbing material is removed, it is necessary to select a solvent having a high selective ratio so as not to dissolve a substance having low wettability. In the case of a dual emission type light emitting display device or a transmissive type liquid crystal display device which extract light from the substrate 100, it is preferable to remove the light-absorbing material since there is a possibility that light extraction efficiency is deteriorated. In the case of a wiring substrate, a top emission type light emitting display device, a reflective type liquid crystal display device, or the like, the light-absorbing material is not necessarily removed.

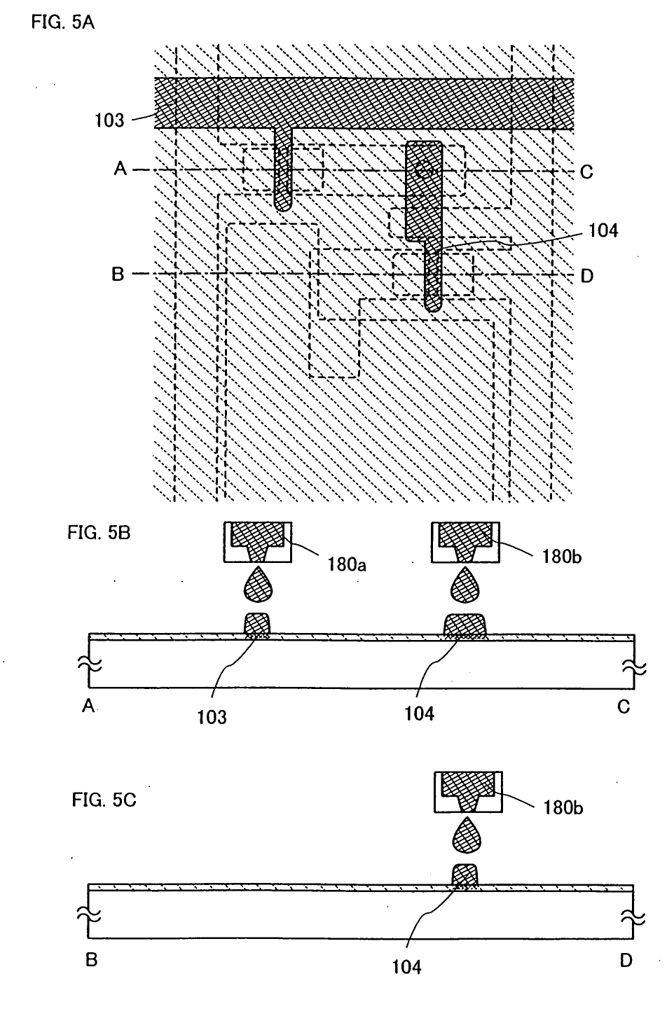

A compound including a conductive material is discharged from droplet discharge devices 180a and 180b to the high-wettability regions 102a and 102b, and gate electrode layers 103 and 104 are formed (see FIGS. 5A to 5C). Even when a discharge opening of a nozzle from which a droplet is discharged is larger than the desirable size, the droplet is attached only to the formation region to form a desired pattern by performing treatment for enhancing wettability on the formation region. This is because the formation region and a region adjacent thereto have different wettability; therefore, the droplet is repelled in the peripheral low-wettability region to remain in a formation region having higher wettability. In other words, the compound including a conductive material is discharged only to the high-wettability regions 102a and 102b and the droplet is repelled by the low-wettability region surrounding a periphery of the high-wettability region; therefore, the boundary between the high-wettability regions 102a and 102b and the low-wettability region formed of the compound 101 having low wettability functions as a partition wall (a bank). A pattern can be formed to have a desired shape since the compound including a conductive material having fluidity can remain in the high-wettability regions 102a and 102b. The width of the narrowed gate electrode layer in the channel direction is 10 μm or less, preferably 5 μm or less.

In this embodiment mode, the high-wettability regions 102a and 102b are formed to have a narrowed portion and a comparatively wide portion, which function as a gate electrode of the gate electrode layers 103 and 104 stably. According to this, an extra compound discharged to the narrowed portion flows the wide region; therefore, a further stable electrode layer can be formed with preferable controllability.

According to the invention, when a minute pattern, for example, an electrode layer or the like is formed, a droplet is not diffused over a formation region even when a discharge opening of the droplet is large somewhat, therefore, a pattern can be made narrower. Additionally, a film thickness of the wiring can be controlled by controlling the amount of the droplet. As in this embodiment mode, when a substance is modified by laser light, a minute process can be performed by being irradiated with the laser light; therefore, a minute wiring, electrode, or the like can be formed with preferable controllability. In addition, by combining a droplet discharge method, the loss of a material can be prevented compared with entire application formation by a spin coating method or the like; therefore, the cost can be reduced.

Additionally, as pretreatment, an organic material which functions as an adhesive agent may be formed to enhance adhesiveness with respect to a pattern formed by a droplet discharge method. In this case, treatment for forming regions having different wettability may be performed over the substance. An organic material (an organic resin material) (polyimide, acrylic), a material in which a skeleton is configured by the bond of silicon (Si) and oxygen (O), and which includes at least hydrogen as a substituent, or at least one of fluoride, an alkyl group, and aromatic hydrocarbon as a substituent may be used.

The gate electrode layers 103 and 104 are formed by using a droplet discharge means. The droplet discharge means is a general term for the one having a means of discharging a droplet such as a nozzle having a discharge opening of a compound or a head equipped with one nozzle or plural nozzles. The diameter of the nozzle included in the droplet discharge means is set in the range of from 0.02 μm to 100 μm (preferably, 30 μm or less) and the amount of the compound to be discharged from the nozzle is set in the range of from 0.001 pl to 100 pl (preferably, 0.1 pl to 40 pl, more preferably, 10 pl or less). The amount of the compound to be discharged increases in proportion to the size of the diameter of the nozzle. Further, it is preferable that the distance between an object to be processed and the discharge opening of the nozzle is as short as possible in order to drop the droplet on a desired position. Favorably, the distance is set approximately in the range of about from 0.1 mm to 3 mm (more preferably, 1 mm or less).

As for the compound to be discharged from the discharge opening, a conductive material dissolved or dispersed in a solvent is used. The conductive material corresponds to a fine particle or a dispersant nano-particle of metal such as Ag, Au, Cu, Ni, Pt, Pd, Ir, Rh, W, or Al, sulfide of metal such as Cd or Zn, oxide of Fe, Ti, Si, Ge, Zr, Ba, or the like, or silver halide. In addition, it also corresponds to indium tin oxide (ITO), ITSO formed of indium tin oxide and silicon oxide, organic indium, organotin, zinc oxide, titanium nitride, or the like which is used as a transparent conductive film. However, as for compounds to be discharged from the discharge opening, it is preferable to use any material of gold, silver, and copper, which is dissolved or dispersed in a solvent, taking a specific resistance value into consideration. It is more preferable to use silver or copper having a low resistance value. When silver or copper is used, a barrier film may be additionally provided as a measure for an impurity. A silicon nitride film or nickel boron (NiB) can be used as the barrier film.

In addition, a particle in which a conductive material is coated with other conductive materials to be a plurality of layers may be used. For example, a three-layer structure particle in which copper is coated with nickel boron (NiB), which is further coated with silver may be used. As for such solvents, esters such as butyl acetate and ethyl acetate; alcohols such as isopropyl alcohol and ethyl alcohol; organic solvents such as methyl ethyl ketone and acetone; or the like may be used. The viscosity of the compound is preferably 20 mPa·s or less. This is because the compound is prevented from drying or the compound is smoothly discharged from the discharge opening. The surface tension of the compound is preferably 40 mN/m or less. However, the viscosity of the compound and the like may be appropriately adjusted in accordance with a solvent to be used and use application. For example, the viscosity of a compound in which ITO, organic indium, or organotin is dissolved or dispersed in the solvent may be set from 5 mPa·s to 20 mPa·s, the viscosity of a compound in which silver is dissolved or dispersed in the solvent may be set from 5 mPa·S to 20 mPa·s, and the viscosity of a compound in which gold is dissolved or dispersed in the solvent may be set from 5 mPa·s to 20 mPa·s.

The conductive layer may be formed by laminating a plurality of conductive materials. In addition, the conductive layer may be formed by a droplet discharge method using silver as a conductive material; thereafter, it may be plated with copper or the like. Plating may be performed by electroplating or a chemical (electroless) plating method. Plating may be performed by soaking a substrate surface into a container filled with a solution having a plating material. A solution having a plating material may be applied so that the solution flows over the substrate surface with the substrate placed obliquely (or vertically). When the plating is performed by applying a solution with the substrate placed vertically, there is an advantage of miniaturizing a process apparatus.

The diameter of a particle of the conductive material is preferably as small as possible for the purpose of preventing clogged nozzles and manufacturing a high-definition pattern, although it depends on the diameter of each nozzle, a desired shape of a pattern, and the like. Preferably, the diameter of the particle of the conductive material is 0.1 μm or less. The compound is formed by a known method such as an electrolyzing method, an atomizing method, a wet reducing method, or the like, and the particle size thereof is typically about from 0.01 μm to 10 μm. However, when a gas evaporation method is employed, a nanomolecule protected with a dispersant is minute, about 7 nm. When each surface of particles is covered with a coating, the nanoparticles do not cohere in the solvent and are uniformly dispersed in the solvent at a room temperature, and show a property similar to that of liquid. Accordingly, it is preferable to use a coating.

In the invention, it is necessary that the compound has fluidity even when it falls to the object to be processed since it is processed to have a desired pattern shape by utilizing the difference in wettability with respect to the fluid compound between a pattern formation region and a region adjacent thereto. However, a process of discharging a compound may be performed under low pressure if fluidity is not omitted. In addition, when the process is performed under low pressure, an oxide film or the like is not formed over the surface of the conductive material; therefore, it is preferable. After discharging the compound, either or both steps of drying and baking is/are performed. Each step of drying and baking is a step of heat treatment. For example, drying is performed for three minutes at 100° C. and baking is performed for from 15 minutes to 30 minutes at temperatures of from 200° C. to 350° C., each of which has a different purpose, temperature, and period. The steps of drying and baking are performed at normal pressure or under low pressure by laser light irradiation, rapid thermal annealing, a heating furnace, or the like. Note that the timing of the heat treatment is not particularly limited. The substrate may be heated to favorably perform the steps of drying and baking. The temperature of the substrate at the time depends on a material of the substrate or the like, but it is typically from 100° C. to 800° C. (preferably, from 200° C. to 350° C.). According to the steps, nanoparticles are made in contact with one another and fusion and welding are accelerated by hardening and shrinking a peripheral resin as well as evaporating the solvent in the compound or chemically removing the dispersant.

A continuous wave or pulsed wave gas laser or solid laser may be used for laser light irradiation. An excimer laser, a YAG laser, and the like can be given as the former gas laser, and a laser using a crystal of YAG or YVO₄ GdVO₄, or the like which is doped with Cr, Nd, or the like can be given as the latter solid lasel Note that it is preferable to use a continuous wave laser in relation to the absorptance of laser light. Moreover, a so-called hybrid laser irradiation method which combines a pulsed wave and a continuous wave may be used. However, it is preferable that the heat treatment by laser light irradiation is instantaneously performed within several microseconds to several tens of seconds so that the substrate 100 is not damaged, depending on heat resistance of the substrate 100. Rapid thermal annealing (RTA) is carried out by raising the temperature rapidly and heating for several microseconds to several minutes using an infrared lamp or a halogen lamp emitting light of from ultraviolet to infrared in an inert gas atmosphere. Since the treatment is performed instantaneously, only a thin film on a top surface can be substantially heated and a lower layer film is not affected. In other words, even a substrate having low heat resistance such as a plastic substrate is not affected.

After forming the gate wiring layers 103 and 104 by discharging a compound by a droplet discharge method, the surface thereof may be planarized by pressing it with pressure to enhance its planarity. As a pressing method, projections may be smoothed by making a roller-shaped object scan on the surface, or the surface may be vertically pressed with a flat plate-shaped object. A heat step may be performed at the time of pressing. Alternatively, a projection portion of the surface may be removed with an air knife by softening or melting the surface with a solvent or the like. A CMP method may be also used for polishing the surface. This step may be applied for planarizing a surface when projections are generated by a droplet discharge method.

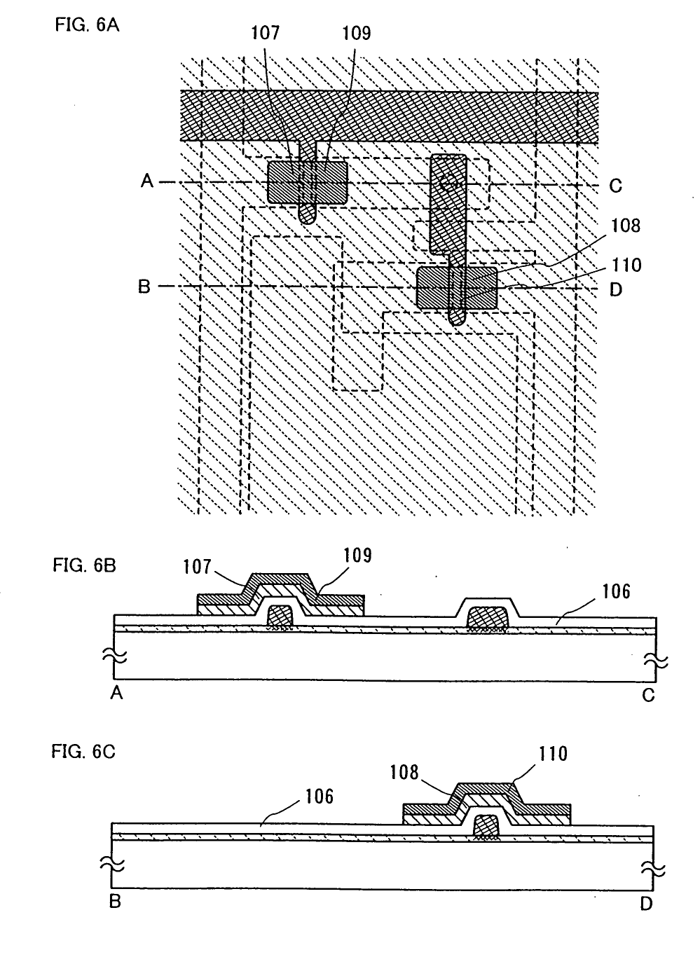

Subsequently, a gate insulating layer 106 is formed over the gate electrode layers 103 and 104 (see FIGS. 6A to 6C). The gate insulating layer 106 may be formed of a known material such as an oxide or nitride material of silicon, and may be a laminated layer or a single layer. In this embodiment mode, a laminated layer of three layers of a silicon nitride film, a silicon oxide film, and a silicon nitride film is used. Alternatively, a single layer of them or of a silicon oxynitride film, or a laminated layer of two layers may be used. A silicon nitride film having minute film quality may be preferably used. In the case of using silver, copper, or the like for the conductive layer formed by a droplet discharge method, and then, forming a silicon nitride film or a NiB film thereover as a barrier film, the silicon nitride film or the NiB film is effective in preventing an impurity from diffusing and in planarizing the surface. Note that a rare gas element such as argon is preferably included in a reactive gas and is preferably mixed into the insulating film to be formed in order to form a minute insulating film with few gate leak current at a low film-formation temperature.

Next, a semiconductor layer is formed. A semiconductor layer having one conductivity may be formed if necessary. In this embodiment mode, semiconductor layers 107 and 108 and N type semiconductor layers 109 and 110 as semiconductor layers having one conductivity are laminated (see FIGS. 6A to 6C). In addition, an NMOS structure of an N-channel TFT in which an N type semiconductor layer is formed, a PMOS structure of a P-channel TFT in which a P type semiconductor layer is formed, and a CMOS structure of an N-channel TFT and a P-channel TFT can be manufactured. In addition, the N-channel TFT and the P-channel TFT can be formed by adding an element which imparts conductivity with doping to impart conductivity and by forming an impurity region in the semiconductor layer.

The semiconductor layers may be formed by a known method (a sputtering method, an LPCVD method, a plasma CVD method, or the like). Although a material for the semiconductor layer is not limited, the semiconductor layer may be formed of a silicon or silicon germanium (SiGe) alloy, or the like.

The semiconductor layer is formed by using an amorphous semiconductor (typically, hydrogenated amorphous silicon), a crystalline semiconductor (typically, polysilicon), or a semi-amorphous semiconductor. Polysilicon (polycrystalline silicon) includes a so-called high temperature polysilicon using polysilicon which is formed through process temperatures of 800° C. or more as a main material, a so-called low temperature polysilicon using polysilicon which is formed through process temperatures of 600° C. or less as a main material, polysilicon crystallized by adding an element or the like which promotes crystallization, or the like.

As another material, a semi-amorphous semiconductor or a semiconductor which contains a crystal phase in a part of the semiconductor layer can also be used.

When a crystalline semiconductor layer is used as the semiconductor layer, a known method (a laser crystallization method, a heat crystallization method, a heat crystallization method using an element promoting crystallization such as nickel, or the like) may be employed as a method for manufacturing the crystalline semiconductor layer. Crystallinity can be can be enhanced by irradiating a microcrystallite which is a SAS with laser light to crystallize. In the case of not introducing an element promoting crystallization, hydrogen is released until hydrogen concentration contained in an amorphous silicon film becomes 1×10²⁰ atoms/cm³ or less by heating the amorphous silicon film for one hour at a temperature of 500° C. in nitrogen atmosphere before irradiating the amorphous silicon film with laser light. This is because a film is damaged when the amorphous silicon film containing much hydrogen is irradiated with laser light.

There is no particular limitation on a method for introducing a metal element into the amorphous semiconductor layer as long as it is a method capable of making the metal element exist on the surface or inside the amorphous semiconductor layer. For example, a sputteing method, a CVD method, a plasma treating method (including a plasma CVD method), an adsorption method, or a method for applying a metal salt solution can be employed. Among them, the method using a solution is simple and easy and is advantageous in terms of easy concentration adjustment of the metal element. It is preferable that an oxide film is formed by UV light irradiation in oxygen atmosphere, a thermal oxidation method, treatment with ozone water or hydrogen peroxide including a hydroxyl radical, or the like in order to improve wettability on the surface of the amorphous semiconductor layer and to spread an aqueous solution over the entire surface of the amorphous semiconductor layer. In addition, heat treatment and laser light irradiation may be combined to crystallize the amorphous semiconductor layer. The heat treatment and/or the laser light irradiation may be independently performed plural times.

A crystalline semiconductor layer may be directly formed over the substrate by a plasma method. Alternatively, a crystalline semiconductor layer may be selectively formed over the substrate by using a plasma method.

An organic semiconductor using an organic material may be used as a semiconductor A low molecular weight material, a high molecular weight material, or the like is used for the organic semiconductor, and in addition, a material such as an organic pigment, a conductive high molecular weight material can be used. For example, pentacene, polythiophene, polyfluorene, and the like can be given.

An amorphous semiconductor is used as the semiconductor in this embodiment mode. The semiconductor layer is formed and then, the N type semiconductor layer is formed as a semiconductor layer having one conductivity by a plasma CVD method or the like.

Subsequently, the semiconductor layer and the N type semiconductor layer are simultaneously patterned using a mask formed of an insulating material such as a resist or polyimide to form the semiconductor layers 107 and 108 and the N type semiconductor layers 109 and 110. The mask can be formed by selectively discharging a compound. A resin material such as an epoxy resin, an acrylic resin, a phenol resin, a novolac resin, a melamine resin, or a urethane resin is used for the mask. In addition, the mask is formed by a droplet discharge method using an organic material such as benzocyclobutene, parylene, flare, or light-transmitting polyimide; a compound material formed by polymerization of a siloxane-based polymer or the like; a material containing a water-soluble homopolymer and a water-soluble copolymer; or the like. Alternatively, a commercially available resist material including a photosensitive agent may be used. For example, a typical positive type resist such as a novolac resin and naphthoquinone diazide compound that is a photosensitive agent, a negative type resist such as a base resin, diphenylsilanediol, and an acid generating agent, or the like may be used. In using any one of the materials, the surface tension and viscosity are appropriately adjusted by adjusting the concentration of a solvent or adding a surfactant or the like.

In this embodiment mode, when the mask is formed by a droplet discharge method, treatment for forming a pattern formation region and a region adjacent thereto to have different wettability may be performed as pretreatment. In the invention, when a pattern is formed by discharging a droplet by a droplet discharge method, the shape of the pattern can be controlled by forming a low-wettability region and a high-wettability region in a pattern formation region. Performing the treatment on a formation region causes difference in wettabilty in the formation region, which makes a droplet remain only in high-wettability formation region. Accordingly, the pattern can be formed with preferable controllability. This step is applicable to pretreatment for forming any patterns in the case of using a liquid material.

Then, a mask formed of an insulating material such as a resist or polyimide is formed by using a droplet discharge method A through-hole 145 is formed in a part of the gate insulating layer 106 by an etching process using the mask, and a part of the gate electrode layer 104 disposed on a lower layer side thereof is exposed. Either plasma etching (dry etching) or wet etching may be adopted as the etching process. However, plasma etching is suitable to treat a large area substrate. A fluorine-based or chlorine-based gas such as CF₄, NF₃, Cl₂, or BCl₃ is used as an etching gas, and an inert gas such as He or Ar may be appropriately added. In addition, a local discharge process can be performed when an atmospheric pressure discharge etching process is applied, and a mask layer need not be entirely formed over the substrate.

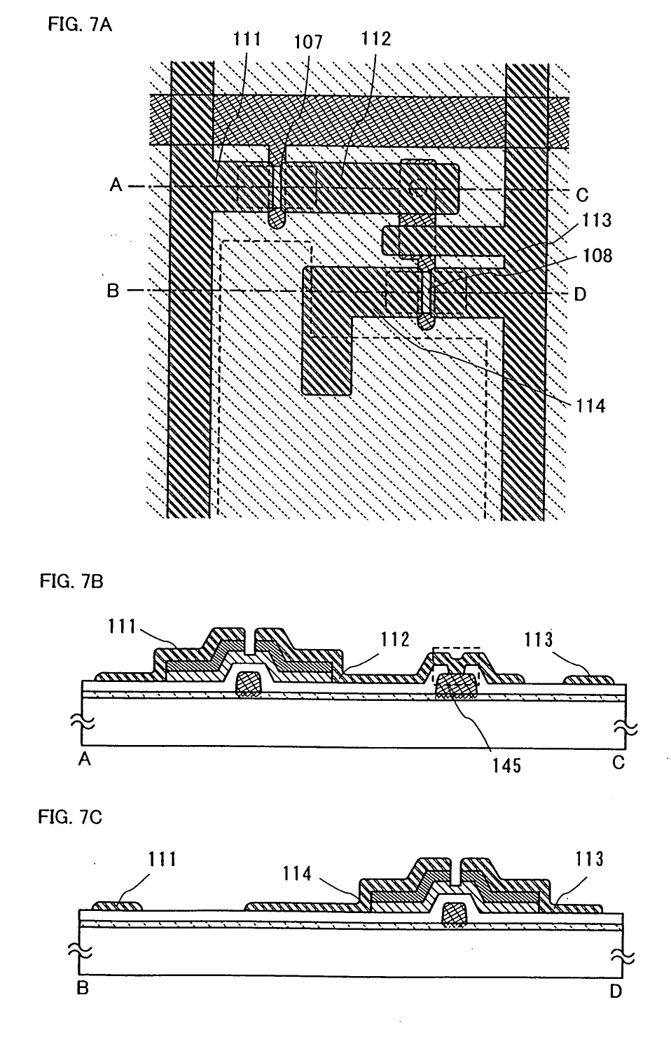

Source/drain electrode layers 111, 112, 113, and 114 are formed by discharging a compound including a conductive material after removing the mask. Then, the semiconductor layers 107 and 108, and the N type semiconductor layers 109 and 110 are patterned using the source/drain electrode layers 111, 112, 113, and 114 as a mask to expose the semiconductor layers 107 and 108 (see FIGS. 7A to 7C). The source/drain electrode layers 111 also functions as a source wiring layer, and the source/drain electrode layer 113 functions also as a power supply line.

Steps for forming the source/drain electrode layers 111, 112, 113, and 114 can be carried out in the same manner as forming the above-mentioned gate electrode layer 104.

As a conductive material for forming the source/drain electrode layers 111, 112 113, and 114, a compound which mainly contains metal particles of Ag (silver), Au (gold), Cu (copper), W (tungsten), Al (aluminum), or the like can be used. Alternatively, indium tin oxide (ITO), ITSO including indium tin oxide and silicon oxide, organic indium, organotin, zinc oxide, titanium nitride, or the like having light-transmitting properties may be combined.

The source/drain electrode layer 112 and the gate electrode layer 104 are electrically connected to each other though the though-hole 145 formed in the gate insulating layer 106. A part of the source/drain electrode layer forms a capacitor element.

A process for forming the though-hole 145 in a part of the gate insulating layer 106 may be performed by using the source/drain electrode layers 111, 112, 113, and 114 as a mask after forming the source/drain electrode layers 111, 112, 113, and 114. A conductive layer is then formed in the though-hole 145 and the source/drain electrode layer 112 and the gate electrode layer 104 are electrically connected. This case has an advantage of simplifying the process.

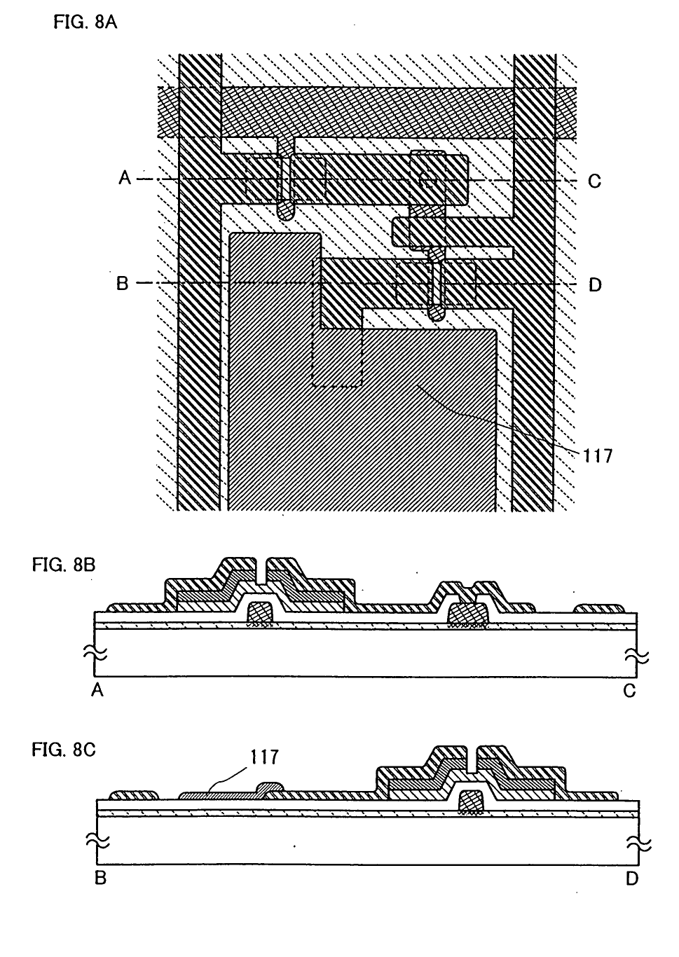

Then, a first electrode layer 117 is formed by selectively discharging a compound including a conductive material over the gate insulating layer 106 (see FIGS. 8A to 8C). When the first conductive layer 117 is formed, naturally, pretreatment for forming a low-wettability region and a high-wettability region may be performed in the same manner as forming the gate electrode layer 104. The first electrode layer 117 can be formed with more preferable controllability and more selectively by discharging a compound including a conductive material over a high-wettability region. When light is emitted from the substrate 100 side, or when a transmissive display panel is manufactured, the first electrode layer 117 may be formed by forming a predetermined pattern using a material including indium tin oxide (ITO), indium tin oxide containing silicon oxide (ITSO), indium zinc oxide (IZO) containing zinc oxide (ZnO), zinc oxide (ZnO), a material in which gallium (Ga) is doped in ZnO, or tin oxide (SnO₂) or the like, and by being baked.

Preferably, the first electrode layer 117 is formed of indium tin oxide (ITO), indium tin oxide containing silicon oxide (ITSO), zinc oxide (ZnO), or the like by a sputtering method. It is more preferable to use indium tin oxide containing silicon oxide formed by a sputtering method using a target in which ITO contains silicon oxide of from 2% to 10% by weight. In addition, a conductive material in which ZnO is doped with gallium (Ga), or an oxide conductive material which contains silicon oxide and in which indium oxide is mixed with zinc oxide (ZnO) of from 2% to 20% by weight may be used. A mask layer may be formed by a droplet discharge method and be etched to have a desired pattern after forming the first electrode layer 117 by a sputtering method. In this embodiment mode, the first electrode layer 117 is formed of a light-transmitting conductive material by a droplet discharge method. Specifically, it is formed by using indium tin oxide or ITSO made of ITO and silicon oxide.

In this embodiment mode, above described is an example of the gate insulating layer made up of three layers of a silicon nitride film, a silicon oxynitride film (silicon oxide film), a silicon nitride film which are formed of silicon nitride. As a preferable structure, the first electrode layer 117 made of indium tin oxide containing silicon oxide is preferably formed close in contact with the insulating layer formed of silicon nitride included in the gate insulating layer 106. Accordingly, an effect of increasing a rate at which light generated in an electroluminescent layer is emitted outside can be caused. The gate insulating layer may be interposed between the gate wiring layer and the source/drain electrode layer or the first electrode layer and may function as a part of a capacitor element.

The first electrode layer 117 can be selectively formed over the gate insulating layer 106 before forming the source/drain electrode layer 114. In this case, this embodiment mode has a connection structure of the source/drain electrode layer 114 and the first electrode layer 117 in which the source/drain electrode layer 114 is laminated over the first electrode layer. When the first electrode layer 117 is formed before forming the source/drain electrode layer 114, it can be formed over a flat formation region. Therefore, the first electrode layer 117 can be formed to have preferable planarity since preferable coverage and deposition properties can be obtained and polishing treatment such as CMP can be carried out sufficiently.

A structure in which an insulating layer which is to be an interlayer insulating layer is formed over the source/drain electrode layer 114 to be electrically connected to the first electrode layer 117 through a wiring layer may be also employed. In this case, instead of forming an opening (contact hole) by removing the insulating layer, a substance having low wettability with respect to the insulating layer is formed over the source/drain electrode layer 114. An insulating layer is formed in a region except for a region where the substance having low wettability is formed when a compound including an insulating layer forming material is applied by an application method or the like.

After forming the insulating layer by curing it by drying or the like, the substance having low wettability is removed to form the opening. The wiring layer is formed so as to fill the opening and the first electrode layer 117 is formed so as to be in contact with the wiring layer. By applying this method, an opening is not necessarily formed by etching; therefore, there is an effect that a process is simplified.

When a reflective type EL display panel is manufactured in the case of a structure in which emitted light is emitted to the opposite side of the substrate 100 side, a compound which mainly contains metal particles of Ag (silver), Au (gold), Cu (copper), W (tungsten), or Al (aluminum), or the like can be used. Alternatively, the first electrode layer 117 may be formed by forming a transparent conductive film or a conductive film having light reflectivity by a sputtering method, forming a mask pattern by a droplet discharge method, and then combining an etching process.

The first conductive layer 117 may be cleaned and polished by a CMP method or by cleaning with polyvinyl alcohol-based porous body so that the surface of the first conductive layer 117 is made flat. In addition, after polishing with the use of a CMP method, ultraviolet irradiation or oxygen plasma treatment or the like may be performed on the surface of the first electrode layer 117.

According to the above-mentioned steps, the substrate 100 having a TFT of a bottom gate type (also referred to as “a reverse stagger type”) and the TFT substrate 100 for a display panel to which a pixel electrode is connected, is completed. The TFT in this embodiment mode is a channel etch type.

Subsequently, an insulating layer (also referred to as a partition wall or a bank) 121 is selectively formed. The insulating layer 121 is formed to have an opening over the first insulating layer 117. In this embodiment mode, the insulating layer 121 is formed over the entire surface, and etched and patterned by using a mask of a resist or the like. When the insulating layer 121 is formed by using a droplet discharge method or a printing method which can form the insulating layer 121 directly and selectively, patterning by etching is not necessarily required. The insulating layer 121 can also be formed to have a desired shape by pretreatment according to the invention.

The insulating layer 121 can be formed of silicon oxide, silicon nitride, silicon oxynitride, aluminum oxide, aluminum nitride, aluminum oxynitride or another inorganic insulating material; acrylic acid, methacrylic acid, or a derivative thereof; a heat-resistant polymer such as polyimide, polybenzimidazole; or an organic siloxane-based insulating material in which an organic group such as methyl or phenyl is substituted for hydrogen bound with silicon or an inorganic siloxane-based material, each of which contains the Si—O—Si bond among a compound including silicon, oxygen and hydrogen, which is formed by using a siloxane material as a start material. The insulating layer 121 may be also formed by using a photosensitive material such as acrylic or polyimide, or a non-photosensitive material. The insulating layer 121 preferably has a shape in which a radius curvature changes continuously. Accordingly, the coverage of an electroluminescent layer 122 and a second electrode layer 123 which are formed over the insulating layer 121 is enhanced.

After forming the insulating layer 121 by discharging a compound by a droplet discharge method, the surface of the insulating layer may be pressed with pressure to planarize in order to enhance its planarity. As a pressing method, projections may be smoothed by scanning a roller-shaped object, or the surface may be vertically pressed with a flat plate-shaped object. Alternatively, a projection portion of the surface may be removed with an air knife by softening or melting the surface with a solvent or the like. A CMP method may be also used to polish the surface. This step may be applied for planarizing the surface when projections are generated by a droplet discharge method. When planarity is enhanced according to the step, display variations or the like of a display panel can be prevented; therefore, a high-definition image can be displayed.

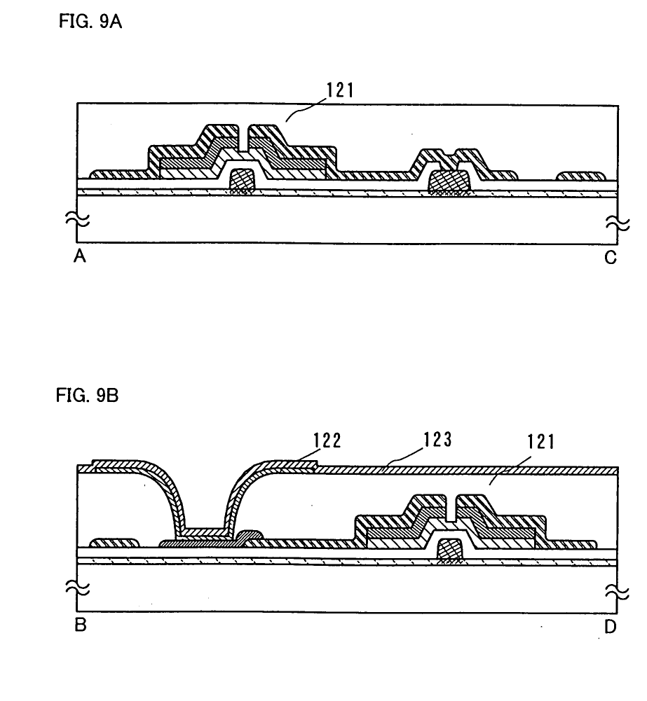

A light emitting element is formed over the substrate 100 having a TFT for a display panel (see FIGS. 9A and 9B).

Before forming the electroluminescent layer 122, moisture in the insulating layer 121 or adsorbed on its surface is removed by performing heat treatment at a temperature of 200° C. under atmospheric pressure. It is preferable to perform heat treatment at temperatures of from 200° C. to 400° C., preferably from 250° C. to 350° C. under low pressure, and to form the electroluminescent layer 122 without being exposed to atmospheric air by a vacuum evaporation method or a droplet discharge method which is performed under low pressure.

As the eletcroluminescent layer 122, materials each indicates the luminescence of red (R), green (G), and blue (B) is selectively formed by an evaporation method using an evaporation mask or the like for each. The materials (low molecular weight materials, high molecular weight materials, or the like) each indicates luminescence of red (R), green (G) and blue (B) can be formed by a droplet discharge method in the same manner as a color filter. This case is preferable since separate coloring of RGB can be carried out even without using a mask. Then, the second electrode layer 123 is laminated over the electroluminescent layer 122 to complete a display device having a display function using a light emitting element.

Although it is not shown, it is effective to provide a passivation film so as to cover the second electrode layer 123. A protective film which is provided at the time of forming a display device may have a single layer structure or a multi-layer structure. As the passivation film, a single layer of an insulating film containing silicon nitride (SiN), silicon oxide (SiO₂), silicon oxynitride (SiON), silicon nitride oxide (SiNO), aluminum nitride (AlN), aluminum oxynitride (AlON), aluminum nitride oxide which has more nitrogen content than oxygen content, aluminum oxide, diamond like carbon (DLC) or a nitrogen-containing carbon film (CNₓ), or a laminated layer in which the insulating films are combined can be used. For example, a laminated layer such as a nitrogen-containing carbon film (CNₓ) and silicon nitride (SiN) or an organic material can be used, or a laminated layer of a polymer such as a styrene polymer may be used. Alternatively, a material which has a skeleton formed by the bond of silicon (Si) and oxygen (O), and which includes at least hydrogen as a substituent, or at least one of fluorine, an alkyl group, and aromatic hydrocarbon as a substituent may be also used.

At this time, it is preferable to use a film having preferable coverage as the passivation film, and a carbon film, particularly, a DLC film is effective. A DLC film can be formed within the temperatures ranging from a room temperature to 100° C. or lower; therefore, a DLC film can be easily formed over an electroluminescent layer having low heat resistance. A DLC film can be formed by a plasma CVD method (typically, an RF plasma CVD method, a microwave CVD method, an electron cyclotron resonance (ECR) CVD method, a heat filament CVD method or the like), a combustion flame method, a sputtering method, an ion beam evaporation method, a laser evaporation method or the like. A hydrogen gas and a hydrocarbon-based gas (for example CH₄, C₂H₂, C₆H₆, or the like) are used as a reactive gas which is used for forming the film. The reaction gas is ionized by glow discharge. The ions are accelerated to collide with a cathode applied with negative self bias. A CN film may be formed by using a C₂H₂ gas and an N₂ gas as a reactive gas. The DLC film has a high blocking effect on oxygen and can suppress the oxidation of the electroluminescent layer. Accordingly, the electroluminescent layer can be prevented from oxidizing during a subsequent sealing step.

Subsequently, a sealant is formed and sealing is performed with a sealing substrate. Then, a flexible wiring substrate may be connected to a gate wiring layer which is formed by being electrically connected to the gate electrode layer 106 to electrically connect to the exterior This is the same for a source wiring layer which is formed by being electrically connected the source/drain electrode layer 111.

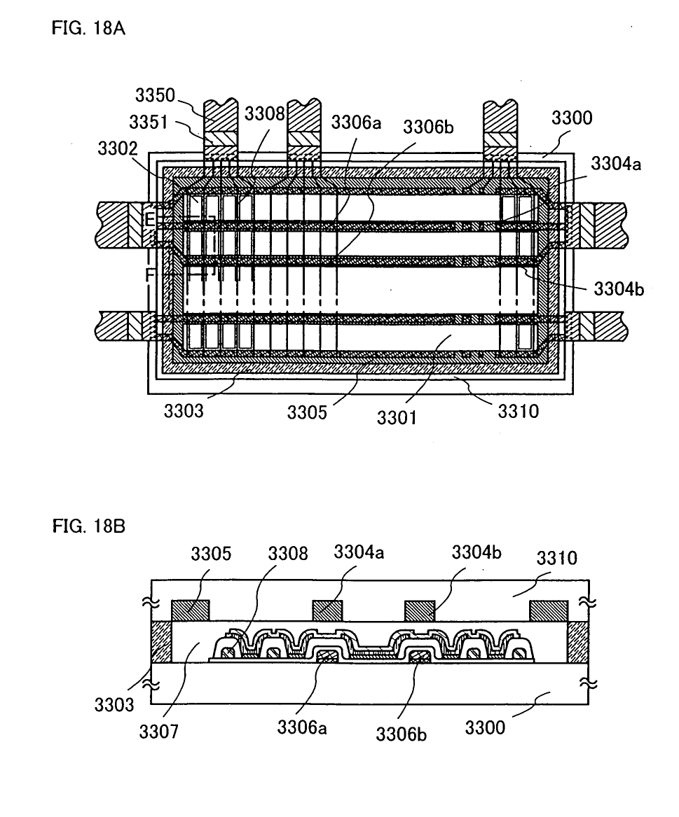

A completion drawing of an EL display panel manufactured by using the invention is shown in FIGS. 18A and 18B. FIG. 18A shows a top view of the EL display panel and FIG. 18B shows a cross-sectional view taken along the line of E-F in FIG. 18A. In FIGS. 18A and 18B, a pixel portion 3301 formed over an element substrate 3300 includes a pixel 3302, gate wiring layers 3306a and 3306b, and a source wiring layer 3308, and the element substrate 3300 is fixed to a sealing substrate 3310 by being bonded with a sealant 3303. In this embodiment mode, a driver IC 3351 is provided over an FPC 3351 and mounted by a TAB method.

As shown in FIGS. 18A and 18B, desiccants 3305, 3304a, and 3304b are provided in a display panel in order to prevent deterioration due to moisture of the element. The desiccant 3305 is formed so as to encircle the circumference of the pixel portion, and the desiccants 3304a and 3304b are formed in a region corresponding to the gate wiring layers 3306a and 3306b. In this embodiment mode, the desiccants are provided in a depressed portion formed in the sealing substrate, which does not prevented an EL display panel from being thinned. A large absorption area can be obtained since a desiccant is formed also in a region corresponding to a gate wiring layer, therefore enhancing an absorption efficiency. Additionally, since the desiccants are formed over the gate wiring layer which does not emit light directly, a light extraction efficiency is not deteriorated. In this embodiment mode, a filler 3307 is filled in a display panel. When a substance having moisture absorption properties such as a desiccant is used as the filler, a further absorption effect can be obtained and the element can be prevented from being deteriorated.

In this embodiment mode, although the case where a light emitting element is sealed with a glass substrate is shown, sealing treatment is treatment to protect a light emitting element from moisture. Therefore, any of a method in which a light emitting element is mechanically sealed with a cover material, a method in which a light emitting element is sealed with a heat-curable resin or an ultraviolet-light-curable resin, and a method in which a light emitting element is sealed with a thin film such as metal oxide, nitride or the like having high barrier capabilities, can be used. As for the cover material, glass, ceramics, plastic or metal can be used. However, when light is emitted to the cover material side, the cover material needs to have light-transmitting properties. Enclosed space is formed by attaching the cover material to the substrate over which the above-mentioned light emitting element is formed with a sealant such as a heat-curable resin or an ultraviolet-light-curable resin and then by curing the resin with heat treatment or ultraviolet irradiation treatment. It is also effective to provide a hydroscopic absorbent material typified by barium oxide in the enclosed space. The absorbent material may be provided over the sealant or over a partition wall or a peripheral part so as not to block light emitted from a light emitting element. Further, it is also possible to fill the space between the cover material and the substrate over which the light emitting element is formed with a heat-curable resin or an ultraviolet-light-curable resin. In this case, it is effective to add a hydroscopic material typified by barium oxide in the heat-curable resin or the ultraviolet-light-curable resin.

In this embodiment mode, although a single gate structure of a switching TFT is shown, a multi-gate structure such as a double gate structure may be also employed. When a semiconductor is manufactured by using a SAS or a crystalline semiconductor, an impurity region can be formed by adding an impurity which imparts one conductivity type. In this case, a semiconductor layer may have an impurity region having different concentration. For example, the semiconductor layer may have a low concentration impurity region in a periphery of a channel formation region and a region which is laminated with a gate electrode layer, and a high concentration impurity region which is outside thereof.

As described above, in this embodiment mode, a photolithography step using a photomask is not employed, and thus steps can be omitted. In addition, a display panel can be easily manufactured by directly forming various patterns over the substrate with the use of a droplet discharge method even when a glass substrate which is in and after the fifth generation having 1000 mm or more on a side is used.

According to the invention, a desired pattern can be formed with preferable controllability, and the loss of a material and the cost can be reduced. Hence, a high-performance and highly reliable display device can be manufactured with a preferable yield.

### Embodiment Mode 3

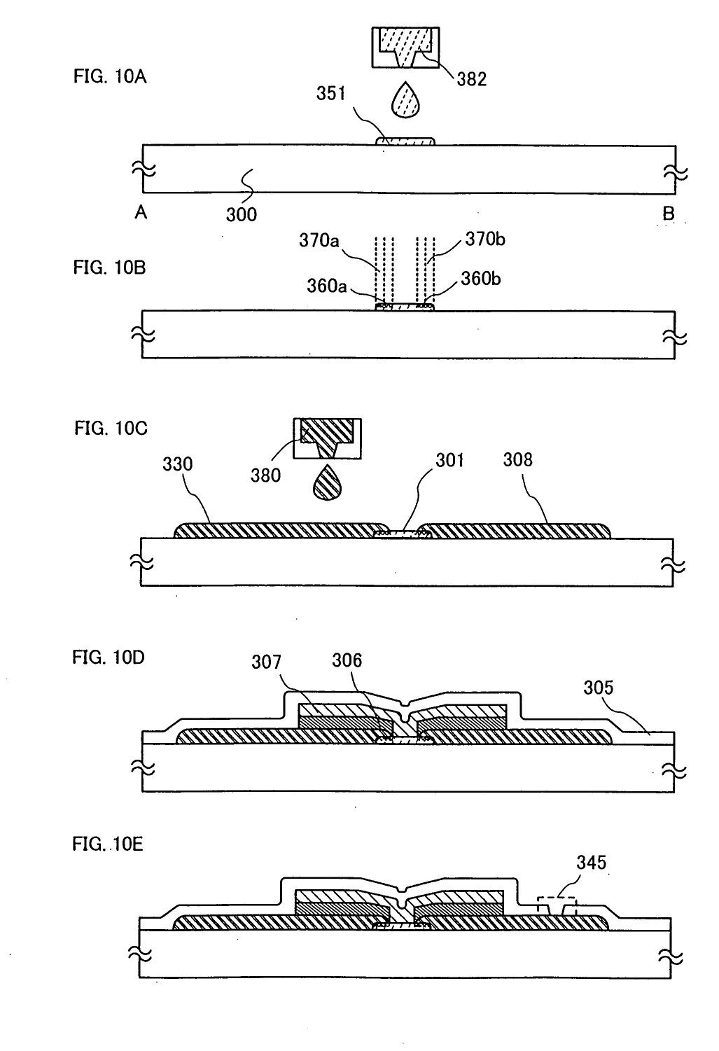

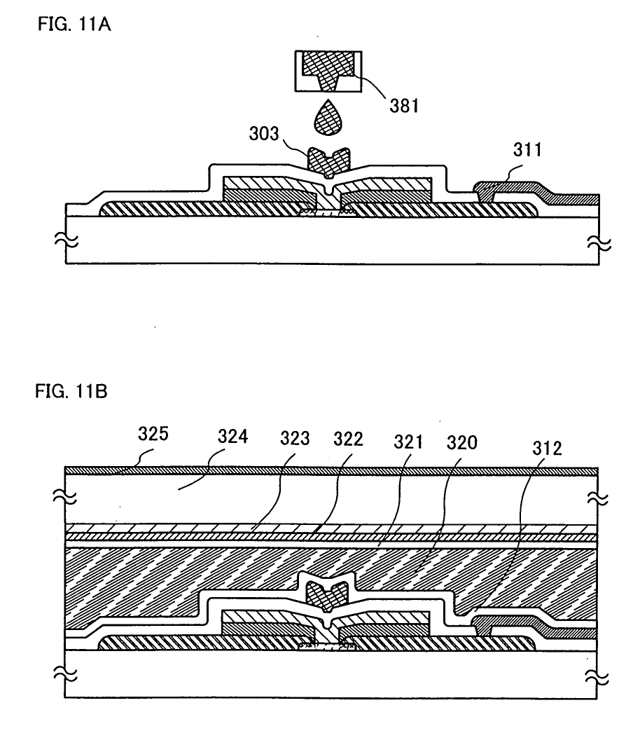

An embodiment mode of the present invention is described with reference to FIGS. 10A to 10E and FIGS. 11A and 11B. In this embodiment mode, a display device is manufactured by using a top gate type (a reverse stagger type) thin film transistor as a thin film transistor. An example of a liquid crystal display device using a liquid material as a display element is shown. Accordingly, the same part or a part having similar function is not repeatedly explained. Note that FIGS. 10A to 10E and FIGS. 11A and 11B show cross-sectional views of the display device.

A pigment is used as a light-absorbing material also in this embodiment mode, and the light absorbing-material is modified so as to change wettability in an irradiation region by laser irradiation treatment. A compound having low wettability in which a light-absorbing material having an absorbing region in a wavelength region of laser light is mixed into a substance having low wettability is discharged over a substrate 300 with a discharge device 382 to form a substance 351 having low wettability.

Both ends of the compound 351 having low wettability is irradiated with laser light 370a and 370b to from high-wettability regions 360a and 360b having high wettability. The laser light is absorbed by the light-absorbing material, which increases irradiation treatment efficiency by being absorbed in the light-absorbing material. As in this embodiment mode, when a film is modified by laser light irradiation, a minute pattern having different wettability can be formed with preferable controllability since minute process is made possible by laser light. Moreover, the cost can be reduced since the loss of a material can be prevented in compared with entire application formation by a spin coating method or the like. A low wettability region 301 which is sandwiched between the high-wettability regions 360a and the high-wettability region 360b has a narrowed-line shape since it is formed by minute process with the use of laser light. In this embodiment mode, a low-wettability region is narrowed by performing irradiation treatment on a plurality of regions such as the high-wettability regions 360a and 306b with laser light. However, the invention is not limited thereto and wettability may be controlled by performing laser light irradiation treatment so as to correspond to the desired interval of wirings. A compound including a conductive material is discharged from a droplet discharging device 380 as a droplet having fluidity so as to across the low-wettability region 301 and to cover the high-wettability regions 360a and 360b.

Accordingly, a discharged compound including a conductive material having fluidity is not stabilized over the low-wettability region 301 because of the difference in the wettability of a formation region, but flows to the high-wettability regions 360a and 360b from the upper surface of the high-wettability regions 360a and 360b. This is because the compound including a conductive material is repelled in the low-wettability region 301 which has low wettability with respect to the compound including a conductive material; therefore, the compound is not fixed and flows to the high-wettability regions 360a, 360b having higher stability. As a result, the shape of the compound including a conductive material is converted into a source/drain electrode layer 330 and a source/drain electrode layer 308 to be stabilized (see FIGS. 10C). Accordingly, an interval between the source/drain electrode layers 330 and 308 can be formed with preferable controllability even though it is narrow, and the source/drain electrode layers 330 and 308 are not in contact with each other. A channel width of a semiconductor becomes narrow according to this; therefore, the resistance is lowered, mobility is increased, and it is formed with preferable controllability resulting in preventing the defect such as a short-circuit. According to the invention, a wiring or the like can be formed with preferable controllability even when a design in which a wiring or the like is integrally and complicatedly disposed since a wiring or the like is miniaturized and thinned is employed.

After forming the electrode layers, a substance which changes wettability formed as pretreatment may be remained, or unnecessary portion may be removed after forming a pattern. A pattern may be used as a mask for the removal, and the unnecessary portion may be removed by ashing with oxygen or the like, etching, or the like. Irradiation treatment using laser light is performed to from a region having different wettability, and then, the light-absorbing material may be removed with a solvent such as alcohol which dissolves the light-absorbing material.

An N type semiconductor layer is formed over the source/drain electrode layers 330 and 308 and is etched with a mask formed of a resist or the like. The resist may be formed by using a droplet discharge method. A semiconductor layer is formed over the N type semiconductor layer and patterned by using a mask or the like again. Accordingly, N type semiconductor layers 307 and 306 are formed.

Then, a gate insulating layer 305 is formed to be a single layer or a laminated structure by using a plasma CVD method or a sputtering method (see FIG. 10D). As a preferable mode, in particular, a laminated body of three layers of an insulating layer 305a including silicon nitride, an insulating layer 305b including silicon oxide, and an insulating layer 305c including silicon nitride corresponds to the gate insulating layer.

Then, a mask formed of a resist or the like is formed over the gate insulating layer 305, and the gate insulating layer 305 is etched to form a through-hole 345 (see FIG. 10E). In this embodiment mode, a mask is selectively formed by a droplet discharge method.

A compound including a conductive material is discharged over the gate insulating layer 305 by a droplet discharge device 381 to form a gate electrode layer 303. As in Embodiment Mode 1, the gate electrode layer can also be formed to have a desired shape and to be further narrower. When the invention is used, a width in the channel direction of the gate electrode layer 303 can be narrowed; therefore, lower resistance and higher mobility can be achieved.

A pixel electrode layer 311 is formed by a droplet discharge method. The pixel electrode layer 311 and the source/drain electrode layer 308 are electrically connected to each other through the through-hole 345 formed before. The same material used for the above-mentioned first electrode layer 117 can be used for the pixel electrode layer 311, and when a transmissive liquid crystal display panel is manufactured, a predetermined pattern is formed by a compound including indium tin oxide (ITO), indium tin oxide containing silicon oxide (ITSO), zinc oxide (ZnO), tin oxide (SnO₂) or the like, and then formed by baking.

An insulating layer 312 called an alignment film is formed by a printing method or a spin coating method so as to cover the pixel electrode layer 311. The insulating layer 312 can be selectively formed with the use of a screen printing method or an offset printing method. Then, rubbing is performed and a sealant is formed in a peripheral region where a pixel is formed by a droplet discharge method (not shown).

Subsequently, a liquid crystal display panel can be manufactured by attaching a counter substrate 324 provided with an insulating layer 321 functioning as an alignment film, a coloring layer 322 functions as a color filter, a conductive layer 323 functioning as a counter electrode, and a counter substrate 324 provided with a polarizing plate 325 to the TFT substrate 300 with a spacer therebetween, and by providing the space with a liquid crystal layer 320 (see FIG. 11B). A sealant may be mixed with a filler, and further, the counter substrate 324 may be provided with a shielding film (a black matrix), or the like. Note that a dispenser type (a dropping type) or a dip type (a pumping type) that injects a liquid crystal by using a capillary phenomenon after attaching the counter substrate 324 can be used as a method for forming the liquid crystal layer.

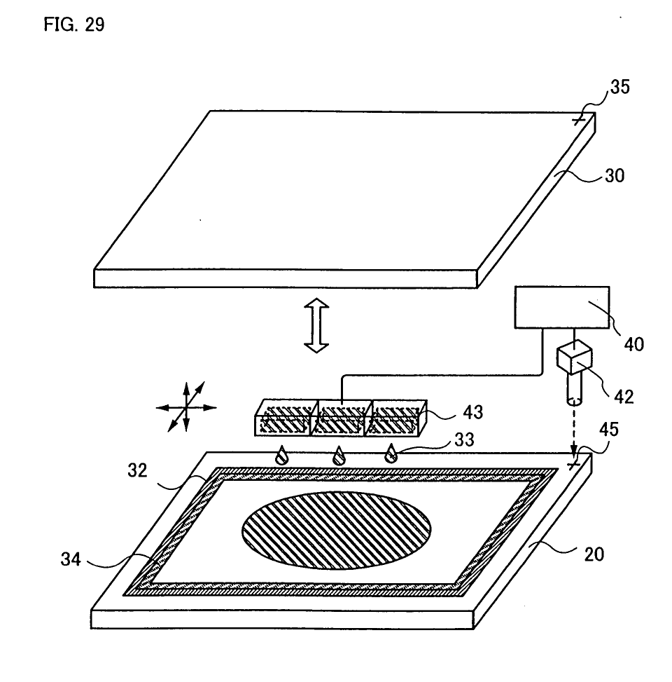

A liquid crystal drop injection method employing a dispenser type is described with reference to FIG. 29. A liquid crystal drop injection method in FIG. 29 includes a control device 40, an image-taking means 42, a head 43, a liquid crystal 33, markers 35 and 45, a barrier layer 34, a sealant 32, a TFT substrate 30, and a counter substrate 20. A closed loop is formed with the sealant 32, and the liquid crystal 33 is dropped once or plural times therein from the head 43. When the liquid crystal material is highly adhesive, the liquid crystal material is continuously discharged and attached to a formation region with being interconnected. On the other hand, when the liquid crystal material is low adhesive, the liquid crystal material is intermittently discharged and a droplet is dropped as in FIG. 29. At this time, the barrier layer 34 is provided to prevent the sealant 32 and the liquid crystal 33 from reacting with each other. Subsequently, the substrates are attached in vacuum, and then, ultraviolet light curing is performed to make the space filled with the liquid crystal.

A connection portion is formed to connect the pixel portion formed in the above step and an external wiring substrate. The insulating layer in the connection portion is removed by ashing treatment using an oxygen gas under the atmospheric pressure or pressure in proximity of the atmospheric pressure. This treatment is performed by using an oxygen gas and one or more gases of hydrogen, CF₄, NF₃, H₂O, and CHF₃. In this step, ashing treatment is performed after sealing by using the counter substrate to prevent damage or destruction due to static, however, ashing treatment may be performed at any timing when there are few effects of static.

A connection wiring substrate is provided so as to electrically connect a wiring layer with an anisotropic conductive layer interposed therebetween. The wiring substrate has a function of transmitting a signal or electric potential from external. Through the above-mentioned steps, a liquid crystal display panel including a display function can be manufactured.

In this embodiment mode, a switching TFT having a single gate structure is described, however, a multi gate structure such as a double gate structure may be employed. When a semiconductor is manufactured with the use of a SAS or crystalline semiconductor, an impurity region can be formed by adding an impurity which imparts one conductivity type. In this case, a semiconductor layer may have impurity regions having different concentration. For example, a region laminated with a gate electrode layer and adjacent to a channel region of a semiconductor layer may be a low concentration impurity region, and the exterior region thereof may be a high concentration impurity region.

As described above, the steps can be omitted in this embodiment mode by not applying a light exposure step utilizing a photomask. In addition, a display panel can be easily manufactured by directly forming various patterns over a substrate with a droplet discharge method even when a glass substrate in and after the fifth generation having 1000 mm or more on a side is used.

According to the invention, a desired pattern can be formed with preferable controllability, and the loss of a material and the cost can be reduced. Hence, a high-performance and highly reliable display device can be manufactured with a preferable yield.

### Embodiment Mode 4

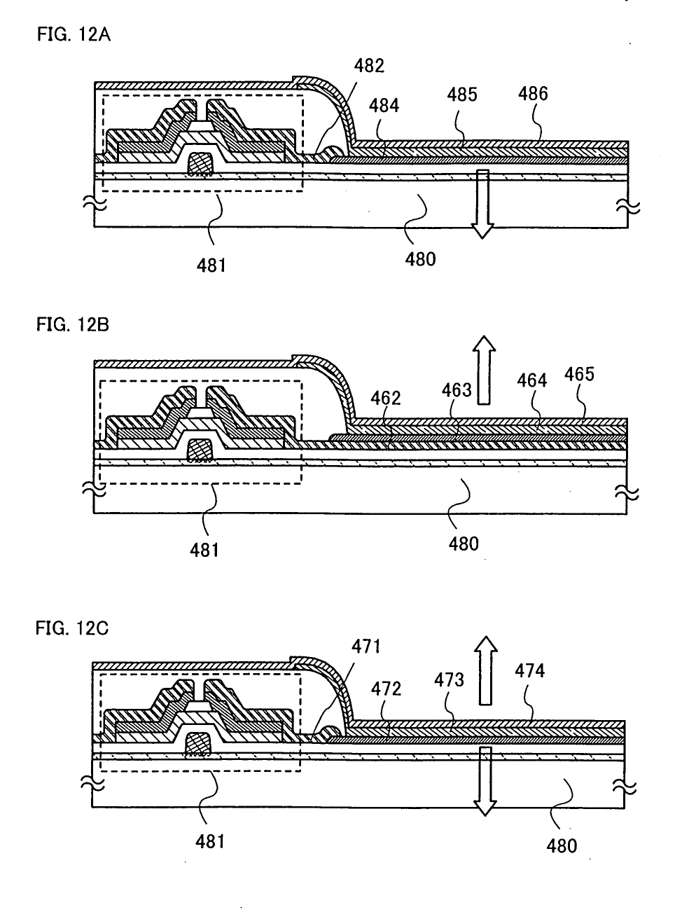

A thin film transistor can be formed by applying the present invention, and a display device can be formed with the use of the thin film transistor In addition, when a light emitting element is used and an N-type transistor is used as a transistor which drives the light emitting element, light emitted from the light emitting element performs any of bottom emission, top emission and dual emission. Here, FIGS. 12A to 12C are used to describe laminated structures of a light emitting element according to each emission.

In this embodiment mode, a channel protective type thin film transistor 481 to which the invention is applied is used. The channel protective film may be formed by dropping polyimide, polyvinyl alcohol or the like with the use of a droplet discharge method. As a result, a photolithography step can be omitted. As the channel protective film, one kind of an inorganic material (silicon oxide, silicon nitride, silicon oxynitride, silicon nitride oxide or the like), a photosensitive or non-photosensitive organic material (an organic resin material) (polyimide, acrylic, polyamide, polyimide amide, a resist, benzocyclobutene or the like), a Low k material which has a low dielectric constant, and the like; a film including plural kinds thereof; a laminated layer thereof; or the like can be used. Additionally, a material which has a skeleton formed by the bond of silicon (Si) and oxygen (O), and which includes at least hydrogen as a substituent, or at least one of fluoride, an alkyl group, and aromatic hydrocarbon as a substituent, may be used. As a manufacturing method, a vapor phase growth method such as a plasma CVD method or a heat CVD method, or a sputtering method can be used. A droplet discharge method or a printing method (a method for forming a pattern, such as a screen printing or offset printing) can also be used. A TOF film or an SOG film obtained by an application method can also be used.

First, the case where light is emitted to the side of a substrate 480, in other words, bottom emission is performed, is described with reference to FIG. 12A. In this case, source/drain electrode 482, a first electrode 484, an electroluminescent layer 485, and a second electrode 486 are sequentially laminated so as to be electrically connected to the transistor 481. Next, the case where light is emitted to the side opposite the substrate 480, in other words, top emission is performed, is described with reference to FIG. 12B. Source/drain electrode 462, a first electrode 463, an electroluminescent layer 464 and a second electrode 465 which are electrically connected to the transistor 481 are sequentially laminated. According to the above-mentioned structure, even when the first electrode 463 transmits light, the light is reflected by the source/drain electrode 462 and emitted to the side opposite the substrate 480. Note that in this structure, it is not necessary to use a material having light-transmitting properties for the first electrode 463. Lastly, the case where light is emitted to both the side of the substrate 480 and the opposite side thereof, in other words, dual emission is performed, is described with reference to FIG. 12C. Source/drain electrode 471, a first electrode 472, an electroluminescent layer 473 and a second electrode 474 which are electrically connected to the transistor 481 are sequentially laminated. At this time, when both the first electrode 472 and the second electrode 474 are formed of a material having light-transmitting properties, or formed to have a film thicknesses which can transmit light, dual emission can be achieved.

A light emitting element has a structure in which the electroluminescent layer is sandwiched between the first electrode and the second electrode. It is necessary to select a material for the first electrode and the second electrode considering a work function. The first electrode and the second electrode can be either an anode or a cathode depending on a pixel structure. In this embodiment mode, it is preferable to make the first electrode a cathode, and the second electrode an anode, since the polarity of a driving TFT is an n-channel type. In addition, when polarity of the driving TFT is a p-channel type, it is preferable to make the first electrode an anode, and the second electrode a cathode.

When the first electrode is an anode, in the electroluminescent layer, it is preferable to laminate an HIL (a hole injection layer), an HTL (a hole transport layer), an EML (a light emitting layer), an ETL (an electron transport layer), and an EIL (an electron injection layer) in order from the anode side. When the first electrode is a cathode, it is preferable to laminate layers adversely, namely, laminate an EIL (an electron injection layer), an ETL (an electron transport layer), an EML (a light emitting layer), an HTL (a hole transport layer), an HIL (a hole injection layer), and a cathode which is the second electrode in order from the cathode side. Additionally, the electroluminescent layer can also be formed with a single layer structure or a combined structure, in addition to a laminated structure.

As the eletcroluminescent layer, materials each indicates luminescence of red (R), green (G), and blue (B) are selectively formed by an evaporation method using an evaporation mask or the like for each. The materials (low molecular weight materials or high molecular weight materials or the like) each indicates luminescence of red (R), green (G), and blue (B) can be formed by a droplet discharge method in the same manner as a color filter. This case is preferable since RGB can be separately colored without using a mask.

In the case of the above top emission type, when ITSO or ITSO having light-transmitting properties are used for the second electrode, BzOS—Li in which Li is added to benzoxazole derivatives (BzOS) or the like can be used. Alq₃ doped with a dopant corresponding to respective luminescent colors of R, G, and B (DCM or the like in the case of R, and DMQD or the like in the case of G) may be used as the EML, for example.

Note that the electroluminescent layer is not limited to the above-mentioned material. For example, hole injectability can be enhanced by co-evaporating oxide such as molybdenum oxide (MoO_{X}: X=2 to 3) and α-NPD or rubrene instead of using CuPc or PEDOT. An organic material (including a low molecular weight material or a high molecular weight material) or a composite material of an organic material and an inorganic material can be used as the material of the electroluminescent layer. A material forming a light emitting element is described in detail hereinafter.

As a substance having high electron transportability among charge injection transport substances, for example, a metal complex having a quinoline skeleton or a benzoquinoline skeleton such as tris(8-quinolinolato)aluminum (abbreviation: Alq₃), tris(5-methyl-8-quinolinolato)aluminum (abbreviation: Almq₃), bis(10-hydroxybenzo[h]-quinolinato)beryllium (abbreviation: BeBq₂), bis(2-methyl-8-quinolinolato)-4-phenylphenolato-aluminum (abbreviation: BAlq), and the like can be given. As a substance having high hole transportability, for example, an aromatic amine compound (in other words, a compound having the bond of benzene ring-nitrogen) such as 4,4′-bis[N-(1-naphthyl)-N-phenyl-amino]-biphenyl (abbreviation: α-NPD), 4,4′-bis[N-(3-methylphenyl)-N-phenyl-amino]-biphenyl (abbreviation: TPD), 4,4′,4″-tris(N,N-diphenyl-amino)-triphenylamine (abbreviation: TDATA), or 4,4′,4″-tris[N-(3-methylphenyl)-N-phenyl-amino]-triphenylamine (abbreviation: MTDATA) can be given.

As a substance having high electron injectability among charge injection transport substances, a compound of an alkali metal or an alkaline earth metal such as lithium fluoride (LiF), cesium fluoride (CsF), or calcium fluoride (CaF₂) can be given. In addition to this, it may be a mixture of a substance having high electron transportability such as Alq₃ and an alkaline earth metal such as magnesium (Mg).

As a substance having high hole injectability among charge injection transport substances, for example, metal oxide such as molybdenum oxide (MoOx), vanadium oxide (VOx), a ruthenium oxide (RuOx), tungsten oxide (WOx), manganese oxide (MnOx) are given. In addition, a phthalocyanine compound such as phthalocyanine (abbreviation: H₂Pc) or copper phthalocyanine (CuPC) can be given.

The light emitting layer may have a structure to perform color display by providing each pixel with light emitting layers having different emission wavelength regions. Typically, a light emitting layer corresponding to color of R (red), G (green), and B (blue) is formed. In this instance, color purity can be improved and a pixel portion can be prevented from having a mirror surface (reflection) by providing the light emitting side of the pixel with a filter which transmits light of an emission wavelength region at the light emission side of the pixel. By providing a filter, a circular polarizing light plate or the like that is conventionally required can be omitted, and further, the loss of light emitted from the light emitting layer can be eliminated. Further, change in hue, which occurs when a pixel portion (display screen) is obliquely seen, can be reduced.

Various materials can be used for a light emitting material. As a low molecular weight organic light emitting material, 4-dicyanomethylene-2-methyl-6-[2-(1,1,7,7-tetramethyl-9-julolidyl)ethenyl]-4H-pyran; (abbreviation: DCJT); 44-dicyanomethylene-2-t-butyl-6-[2-(1,1,7,7-tetramethyljulolidine-9-yl-ethenyl)]-4H-pyran; (abbreviation: DCJTB); Periflanthene; 2,5-dicyano-1,4-bis[2-(10-methoxy-1,1,7,7-tetramethyljulolidine-9-yl)ethenyl]benzene; N,N′-dimethylquinacridon (abbreviation: DMQd); coumarin 6; coumarin 545T; tris(8-quinolinolato)aluminum (abbreviation: Alq₃); 9.9′-bianthryl; 9,10-diphenylanthracene (abbreviation: DPA); 9,10-bis(2-naphthyl)anthracene (abbreviation: DNA); and the like can be used. Another substance can also be used.

On the other hand, a high molecular weight organic light emitting material is physically stronger than a low molecular weight material and is superior in durability of the element. In addition, a high molecular weight organic light emitting material can be formed by application, and therefore, the element can be relatively easily manufactured. The structure of a light emitting element using a high molecular weight organic light emitting material has basically the same structure as in the case of using a low molecular weight organic light emitting material, that is, a cathode, an organic light emitting layer, and an anode are laminated in order. However, a two-layer structure is employed in many cases when a light emitting layer using a high molecular weight organic light emitting material is formed. This is because it is difficult to form such a laminated structure as in the case of using a low molecular weight organic light emitting material. Specifically, the light emitting element using a high molecular weight organic light emitting material has a structure of a cathode, a light emitting layer, a hole transport layer, and an anode in order.

A emission color of is determined depending on a material forming a light emitting layer; therefore, a light emitting element which indicates desired luminescence can be formed by selecting an appropriate material of the light emitting layer. As a high molecular weight electroluminescent material which can be used for forming a light emitting layer, a polyparaphenylene-vinylene-based material, a polyparaphenylene-based material, a polythiophene-based material, a polyfluorene-based material can be given.

As the polyparaphenylene vinylene-based material, a derivative of poly(paraphenylenevinylene) [PPV], for example, poly(2,5-dialkoxyl,4-phenylenevinylene) [RO-PPV]; poly(2-(2′-ethyl-hexoxy)-5-methoxy-1,4-phenylenevinylene) [MEH-PPV]; poly(2-(dialkoxyphenyl)-1,4-phenylenevinylene) [ROPh-PPV]; and the like can be given. As the polyparaphenylene-based material, a derivative of polyparaphenylene [PPP], for example, poly(2,5-dialkoxy-1,4-phenylene) [RO-PPP]; poly(2,5-dihexoxy-1,4-phenylene); and the like can be given. As the polythiophene-based material, a derivative of a derivative of polythiophene [PT], for example, poly(3-alkylthiophene) [PAT]; poly(3-hexylthiophen) [PHT]; poly(3-cyclohexylthiophen) [PCHT]; poly(3-cyclohexyl-4-methylthiophene) [PCHMT]; poly(3,4-dicyclohexylthiophene) [PDCHT]; poly[3-(4-octylphenyl)-thiophene] [POPT]; poly[3-(4-octylphenyl)-2,2bithiophene] [PTOPT]; and the like can be given. As the polyfluorene-based material, a derivative of polyfluorene [PF], for example, poly(9,9-dialkylfluorene) [PDAF]; poly(9,9-dioctylfluorene) [PDOF]; and the like can be given.

When a high molecular weight organic light emitting material having hole transportability is interposed between an anode and a high molecular weight organic light emitting material having light emitting properties, hole injectability from the anode can be enhanced. Generally, the high molecular weight organic light emitting material having hole transportability which is dissolved in water along with an acceptor material is applied by a spin coating method or the like. In addition, the high molecular weight light emitting material having hole injectability is insoluble in an organic solvent; therefore, it can be laminated over the above-mentioned high molecular weight organic light emitting material having light emitting properties. As the high molecular weight organic light emitting material having hole transportablity, a mixture of PEDOT and camphor-10-sulfonic acid (CSA) that serves as an acceptor material, a mixture of polyaniline [PANI] and polystyrene sulfonic acid [PSS] that serves as an acceptor material, and the like can be given.

The light emitting layer can be made to emit plain color or white light. When a white light emitting material is used, color display can be made possible by applying a structure in which a filter (a coloring layer) which transmits light having a specific wavelength on the light emitting side of a pixel is provided.

In order to form a light emitting layer that emits white light, for example, Alq₃, Alq₃ partly doped with Nile red that is a red light emitting pigment, Alq₃, p-EtTAZ, TPD (aromatic diamine) are laminated sequentially by a vapor deposition method to obtain white light. In the case that the light emitting layer is formed by an application method using spin coating, the layer formed by spin coating is preferably baked by vacuum heating. For example, an aqueous solution of poly(ethylene dioxythiophene)/poly(styrene sulfonic acid) solution (PEDOT/PSS) may be entirely applied and baked to form a film that functions as a hole injection layer. Then, a polyvinyl carbazole (PVK) solution doped with a luminescent center pigment (1,1,4,4-tetraphenyl-1,3-butadiene (TPB); 4-dicyanomethylene-2-methyl-6-(p-dimethylamino-styryl)-4H-pyran (DCM1); Nile red; coumarin 6; or the like) may be entirely applied and baked to form a film that functions as a light emitting layer.

The light emitting layer may be formed to be a single layer. For example, a 1,3,4-oxadiazole derivative (PBD) having electron transportability may be dispersed in polyvinyl carbazole (PVK) having hole transporatbility. Further, white light emission can be obtained by dispersing PBD of 30 wt % as an electron transporting agent and dispersing an appropriate amount of four kinds of pigments (TPB, coumarin 6, DCM1, and Nile red). In addition to the light emitting element from which white light emission can be obtained as shown here, a light emitting element which can provide red light emission, green light emission, or blue light emission can be manufactured by appropriately selecting materials of the light emitting layer.

When a high molecular weight organic light emitting material having hole transportability is formed by being interposed between an anode and a high molecular weight organic light emitting material having light emitting properties, hole injectability from the anode can be enhanced. Generally, the high molecular weight light emitting material having hole transportability which is dissolved in water along with an acceptor material is applied by a spin coating method or the like. In addition, the a high molecular weight light emitting material having hole transportability is insoluble in an organic solvent; therefore, it can be laminated over the above-mentioned organic light emitting material having light emitting properties. As the high molecular weight organic light emitting material having hole transportability, a mixture of PEDOT and camphor-10-sulfonic acid (CSA) that functions as an acceptor material, a mixture of polyaniline [PANI] and polystyrene sulfonic acid [PSS] that functions as an acceptor material, and the like can be given.

Further, a triplet excitation material containing a metal complex or the like as well as a singlet excitation light emitting material may be used for the light emitting layer. For example, among pixels emitting red, green, and blue light, a pixel emitting red light whose luminance is reduced by half in a relatively short time is formed of a triplet excitation light emitting material and the rest are formed of a singlet excitation light emitting material. A triplet excitation light emitting material has a characteristic that the material has a good luminous efficiency and consumes less power to obtain the same luminance. When a third excitation light emitting material is used for a red pixel, only small amount of current needs to be applied to a light emitting element. Thus, reliability can be improved. A pixel emitting red light and a pixel emitting green light may be formed of a triplet excitation light emitting material and a pixel emitting blue light may be formed of a singlet excitation light emitting material to achieve low power consumption. Low power consumption can be further achieved by forming a light emitting element which emits green light that has high visibility with a triplet excitation light emitting material.

A metal complex used as a dopant is an example of a triplet excitation light emitting material, and a metal complex having platinum that is a third transition series element as a central metal, a metal complex having iridium as a central metal, and the like are known. A triplet excitation light emitting material is not limited to the compounds. A compound having the above described structure and an element belonging to any of the Groups 8 to 10 of the periodic table as a central metal can also be used.

The above described materials for forming the light emitting layer are just examples. A light emitting element can be formed by appropriately laminating functional layers such as a hole injection transport layer, a hole transport layer, an electron injection transport layer, an electron transport layer, a light emitting layer, an electron blocking layer, and a hole blocking layer. Further, a mixed layer or a mixed junction may be formed by combining these layers. The layer structure of the light emitting layer can be varied. Instead of providing a specific electron injection region or light emitting region, modification such as providing an electrode for the purpose or providing a dispersed light emitting material is acceptable as long as it does not deviate from the scope of the invention.

A light emitting element formed with the above described materials emits light by being biased in a forward direction. A pixel of a display device formed with a light emitting element can be driven by a simple matrix mode or an active matrix mode. In any event, each pixel emits light by applying a forward bias thereto in specific timing; however, the pixel is in a non-light-emitting state for a certain period. Reliability of a light emitting element can be improved by applying a backward bias at this non-light-emitting time. In a light emitting element, there is a deterioration mode in which emission intensity is decreased under specific driving conditions or a deterioration mode in which a non-light-emitting region is enlarged in the pixel and luminance is apparently decreased. However, progression of deterioration can be slowed down by alternating current driving. Thus, reliability of a light emitting device can be improved. Additionally, both of digital driving and analog driving can be applied.

A color filter (coloring layer) may be formed over the counter substrate of the substrate 480 although it is not shown in FIGS. 12A to 12C. The color filter (coloring layer) can be formed by a droplet discharge method, and in this case, laser light irradiation treatment can be applied as the above-mentioned base pretreatment. According to the invention, a color filter (coloring layer) can be formed to have a desired pattern with preferable controllability. With the use of a color filter (coloring layer), high-definition display can also be performed. This is because a broad peak can be modified to be sharp in light emitting spectrum of each RGB.

As described above, the case where a material indicating luminescence of R, G, and B is shown, however, full color display can be performed by forming a material indicating a monochrome color and combining a color filter and a color conversion layer. The color filter (coloring layer) or the color conversion layer is formed over, for example, a second substrate (a sealing substrate) and may be attached to a substrate. As described above, any of the material indicating a plain color, the color filter (coloring layer), and the color conversion layer can be formed by a droplet discharge method.

Naturally, a plain color may be displayed. For example, a display device having an area color type may be manufactured by using plain color emission. A passive matrix type display portion is suitable for the area color type, and a letter or a signal can be mainly displayed.

In the above-mentioned structure, it is possible to use a material having a low work function as a cathode, and for example, Ca, Al, CaF, MgAg, AlLi, or the like is desirable. Any of a single layer type, a laminated layer type, a mixed type having no interface of layers can be used for the electroluminescent layer. The electroluminescent layer may be formed by a singlet material, a triplet material, or a material in which the materials are mixed; or a charge injection transport substance and a light emitting material including an organic compound or an inorganic compound, which includes one layer or plural layers of a low molecular weight organic compound material, a middle molecular weight organic compound (which means an organic compound having no sublimation properties, and the number of molecules is 20 or less or the length of liked molecules is 10 μm or less), and a high molecular weight organic compound, which are defined by the number of molecules, and may be combined with an electron injection transport inorganic compound or a hole injection transport inorganic compound. The first electrode 484, the first electrode 463, and the first electrode 472 are formed by using a transparent conductive film which transmits light, and for example, a transparent conductive film in which zinc oxide (ZnO) of 2% to 20% is mixed in indium oxide is used in addition to ITSO or ITSO. Plasma treatment or heat treatment in vacuum atmosphere may be preferably performed before forming the first electode 484, the first electrode 463, and the first electrode 472. The partition wall (also referred to as a bank) is formed by using a material containing silicon, an organic material or a compound material. Additionally, a porous film may be used. However, when a photosensitive material or a non-photosensitive material such as acrylic or polyimide is used to form, the side face thereof has a shape in which a radius curvature changes continuously and a disconnection due to a step is not generated in an upper layer thin film; therefore, it is preferable. This embodiment node can be freely combined with the above-mentioned embodiment modes.

### Embodiment Mode 5

### Embodiment Mode 3

In a display panel manufactured according to Embodiment Modes 2 to 4, as explained in FIG. 14B, a scanning line driver circuit can be formed over a substrate 3700 by forming a semiconductor layer of a SAS.

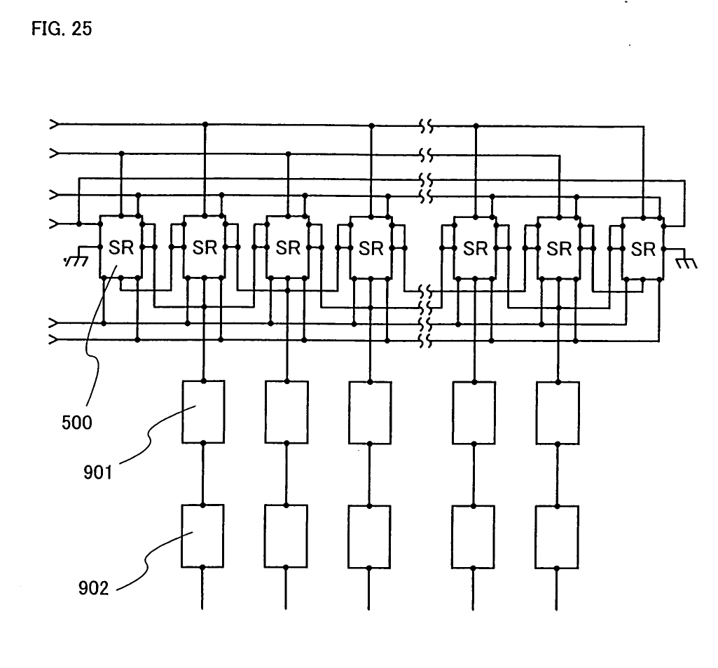

FIG. 25 shows a block diagram of the scanning line driver circuit including n-channel type TFTs using a SAS in which electric field effect mobility of from 1 cm²/V·sec to 15 cm²/V·sec can be obtained.

In FIG. 25, a block 500 corresponds to a pulse output circuit outputting a sampling pulse for one stage and a shift register includes n pulse outputting circuits. Reference numeral 901 denotes a buffer circuit and connected to a pixel 902.

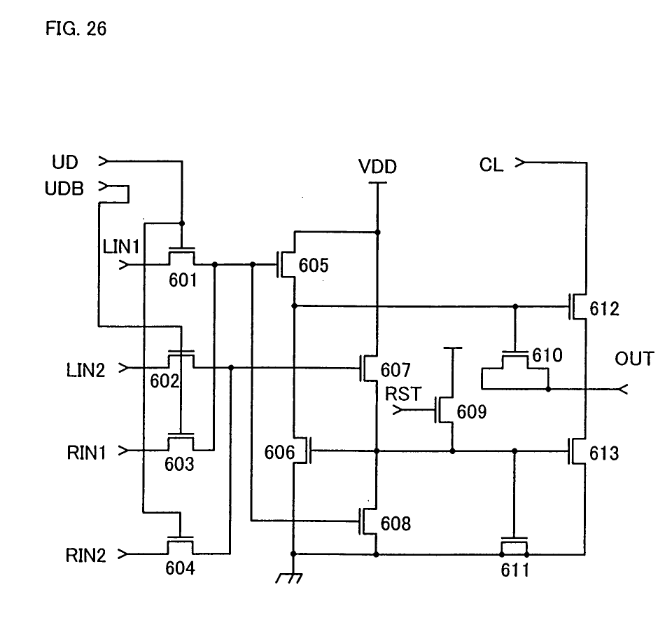

FIG. 26 shows a specific structure of the pulse output circuit 500 shown by the block 500, and this pulse output circuit 500 includes n-channel type TFTs 601 to 613. The size of the TFTs may be decided in consideration of the operating characteristics of the n-channel type TFTs using a SAS. For example, when a channel length is set to be 8 μm, the channel width can be set ranging from 10 μm to 80 μm.

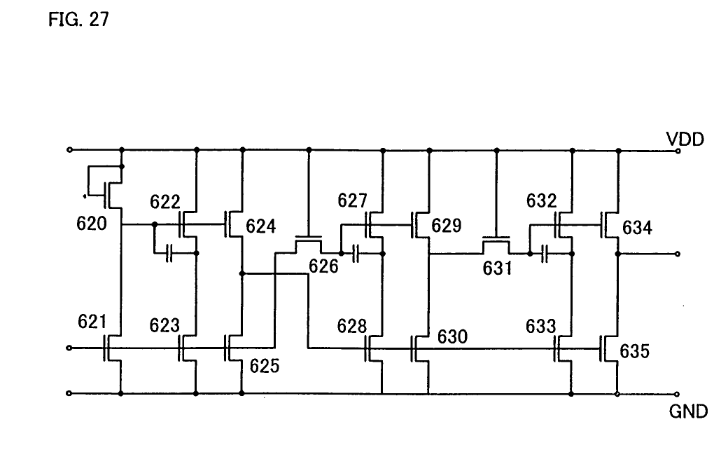

In addition, FIG. 27 shows a specific structure of the buffer circuit 901. The buffer circuit includes n-channel type TFTs 620 to 635 in the same manner. At this time, the size of the TFTs may be decided in consideration of the operating characteristics of the n-channel type TFTs using a SAS. For example, when a channel length is set to be 10 μm, the channel width can be set ranging from 10 μm to 1800 μm. According to the present invention, a pattern can be formed to have a desired shape with preferable controllability; therefore, a narrow wiring like this having a channel width of 10 μm can be stably formed without a break.

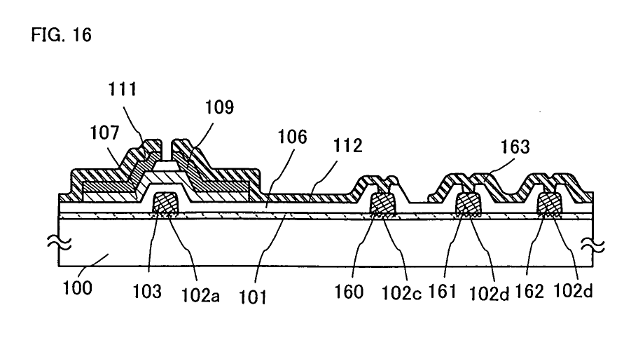

It is necessary to connect the TFTs with one another by wirings to realize such a circuit, and FIG. 16 shows a structure example of wirings in the case thereof. As well as in Embodiment Mode 4, FIG. 16 shows a state in which a gate electrode layer 103, a gate insulating layer 106 (a lamination body of three layer including an insulating layer containing silicon nitride, an insulating layer containing silicon oxide, and an insulating layer containing silicon nitride), a semiconductor layer 107 formed of a SAS, an n-type semiconductor layer 109 which forms a source/drain, and source/drain electrode layers 111 and 112 are formed. In this case, connection wiring layers 160, 161, and 162 are formed over a substrate 100 in the same step as that of the gate electrode layer 103. A substance having low wettability including a light-absorbing material is formed over the substrate 100, and irradiation treatment with the use of laser light having a wavelength absorbed by the light-absorbing material is performed on regions where the gate electrode layer 103, the connection wiring layers 160, 161, and 162 are to be formed. Hence, treated regions becomes high-wettability regions 102a, 102b, 102c, and 102d compared with the surrounding areas. Then, a part of the gate insulating layer is etching-processed such that the connection wiring layers 160, 161, and 162 are exposed, and various circuits can be achieved by appropriately connecting the TFTs through the source/drain electrode layers 111 and 112 and the connection wiring layer 163 formed in the same step thereof.

### Embodiment Mode 6

A mode of mounting a driver circuit on a display panel manufactured according to Embodiment Modes 2 to 5 is described.

First, a display device employing a COG method is described with reference to FIG. 15A. A pixel portion 2701 for displaying information on characters, images or the like is provided over a substrate 2700. A substrate provided with a plurality of driver circuits is divided into rectangles, and the divided driver circuits (hereinafter referred to as a driver IC) 2751 are mounted on the substrate 2700. FIG. 15A shows a mode of mounting a plurality of driver ICs 2751 and an FPC 2750 on the end of the driver ICS 2751. In addition, a divided size may be made almost the same as the length of a side of a pixel portion on a signal line side, and a tape may be mounted on the end of a singular driver IC.

A TAB method may be adopted. In that case, a plurality of tapes may be attached and driver ICs may be mounted on the tape. Similarly to the case of a COG method, a singular driver IC may be mounted on a singular tapes. In that case, a metal piece or the like for fixing the driver IC may be attached together in terms of the matter of intensity.

A plurality of the driver ICs to be mounted on a display panel is preferably formed over the rectangular substrate having a side of from 300 mm to 1000 mm or more in terms of improving productivity.

In other words, a plurality of circuit patterns including a driver circuit portion and an input-output terminal as a unit is formed over the substrate, and may be lastly divided and taken out. In consideration of a side length of the pixel portion and the pixel pitch, the driver IC may be formed to be a rectangle having a long side of from 15 mm to 80 mm and a short side of from 1 mm to 6 mm. Alternatively, the driver IC may be formed to have the long side length of a side length of the pixel portion, or the long side length of adding the pixel portion to a side length of each driver circuit.

An advantage of the external dimension over an IC chip of a driver IC is the length of a long side. When a driver IC having a long side of from 15 mm to 80 mm is used, the number necessary for mounting in accordance with the pixel portion is less than that in the case of using an IC chip. Therefore, a yield in manufacturing can be improved. When a driver IC is formed over a glass substrate, productivity is not harmed, without limitation due to the shape of a substrate used as a mother body. This is a great advantage compared with the case of taking IC chips out of a circular silicon wafer.

When a scanning line driver circuit 3702 is integrally formed over the substrate as shown in FIG. 14B, the driver IC provided with a signal line driver circuit is mounted on a region outside the pixel portion 3701. The driver IC is a signal line side driver circuit. In order to form a pixel portion corresponding to RGB full color, 3072 signal lines are required for an XGA class and 4800 signal lines are required for a UXGA class. The signal lines formed in such a number are divided into several blocks on an edge portion of the pixel portion 3701 and are provided with a lead line. The signal lines are gathered in relation to pitches of output terminals of the driver IC.

The driver IC is preferably made of a crystalline semiconductor formed over a substrate. The crystalline semiconductor is preferably formed by being irradiated with continuous wave laser light. Therefore, a continuous wave solid laser or gas laser is used as an oscillator for generating the laser light. There are few crystal defects when a continuous wave laser is used, and as a result, a transistor can be formed by using a polycrystalline semiconductor layer with a large grain size. In addition, high-speed driving is possible since mobility or response speed is favorable, and it is possible to further improve an operating frequency of an element than that of the conventional element. Therefore, high reliability can be obtained since there are few characteristics variations. Note that the channel-length direction of a transistor and a scanning direction of laser light may be directed in the same direction to further improve an operating frequency. This is because the highest mobility can be obtained when a channel length direction of a transistor and a scanning direction of laser light with respect to a substrate are almost parallel (preferably, from −30° to 30°) in a step of laser crystallization by a continuous wave laser. The channel length direction coincides with the flowing direction of a current, in other words, a direction in which an electric charge moves in a channel formation region. The thus manufactured transistor has an active layer including a polycrystalline semiconductor layer in which a crystal grain is extended in the channel direction, and this means that a crystal grain boundary is formed almost along the channel direction.

In order to perform laser crystallization, it is preferable to largely narrow down the laser light, and the beam spot thereof preferably has the same width as that of a short side of the driver ICs, approximately from 1 mm to 3 mm. In addition, in order to secure an enough and effective energy density for an object to be irradiated, an irradiation region of the laser light is preferably in a linear shape. As used herein, the term “linear” refers to not a line in a strict sense but a rectangle or an oblong with a large aspect ratio. For example, the linear shape refers to a rectangle or an oblong with an aspect ratio of 2 or more (preferably from 10 to 10000). Thus, it is possible to provide a method for manufacturing a display device in which productivity is improved by making a beam spot width of the laser light and that of a short side of the driver ICs to have the same length.

As shown in FIGS. 15A and 15B, driver ICs may be mounted as both a scanning line driver circuit and a signal line driver circuit. In this case, it is preferable to differentiate specifications of the scanning line driver circuit and the signal line driver circuit.

In the pixel portion, the signal line and the scanning line intersect to form a matrix and a transistor is arranged in accordance with each intersection. A TFT having an amorphous semiconductor or a semi-amorphous semiconductor as a channel portion is used as the transistor arranged in the pixel portion in the present invention. The amorphous semiconductor is formed by a method such as a plasma CVD method or a sputtering method. It is possible to form the semi-amorphous semiconductor at temperatures of 300° C. or less by a plasma CVD method. A film thickness necessary to form a transistor is formed in a short time even in the case of a non-alkaline glass substrate of an external size of, for example, 550 mm×650 mm. The feature of such a manufacturing technique is effective in manufacturing a large-area display device. In addition, a semi-amorphous TFT can obtain field effect mobility of from 2 cm²/V·sec to 10 cm²/V·sec by forming a channel formation region of a SAS. When the invention is applied, a narrow wiring having a short channel width can be stably formed without a break since a pattern can be formed to have a desired shape with preferable controllability. Accordingly, TFT having electric characteristics required to function a pixel sufficiently. Therefore, this TFT can be used as a switching element of pixels and as an element constituting the scanning line driver circuit. Thus, a display panel in which system-on-panel is realized can be manufactured.

The scanning line driver circuit is also integrally formed over the substrate by using a TFT having a semiconductor layer formed of a semi-amorphous semiconductor (SAS). In the case of using a TFT having a semiconductor layer formed of an amorphous semiconductor (AS), a driver IC may be mounted as both the scanning line driver circuit and the signal line driver circuit.

In that case, it is preferable to differentiate specifications of the driver ICs to be used on the scanning line and on the signal line. For example, a transistor constituting the scanning line side driver ICs is required to withstand a voltage of approximately 30 V, however, a drive frequency is 100 kHz or less and high-speed operation is not comparatively required. Therefore, it is preferable to set a channel-length (L) of the transistor included in the scanning line driver sufficiently long. On the other hand, a transistor of the signal line driver ICs is required to withstand a voltage of only approximately 12 V, however, a drive frequency is around 65 MHz at 3 V and high-speed operation is required. Therefore, it is preferable to set a channel-length or the like of the transistor included in a driver with a micron rule. According to the invention, a minute pattern can be formed by treatment using laser irradiation; therefore, the invention can correspond to such a micron rule sufficiently.

A method for mounting a driver IC is not particular limited and a known method such as a COG method, a wire bonding method, or a TAB method can be employed.

The heights of the driver IC and the counter substrate can be made almost the same by forming the driver IC to have the same thickness as that of the counter substrate, which contributes to thinning a display device as a whole. When both substrates are formed of the identical material, thermal stress is not generated and characteristics of a circuit including a TFT are not harmed even when temperature change is generated in the display device. Furthermore, the number of driver ICs to be mounted on one pixel portion can be reduced by mounting a longer driver IC than an IC chip as a driver circuit as described in this embodiment mode.

As described above, a driver circuit can be incorporated in a display panel.

### Embodiment Mode 7

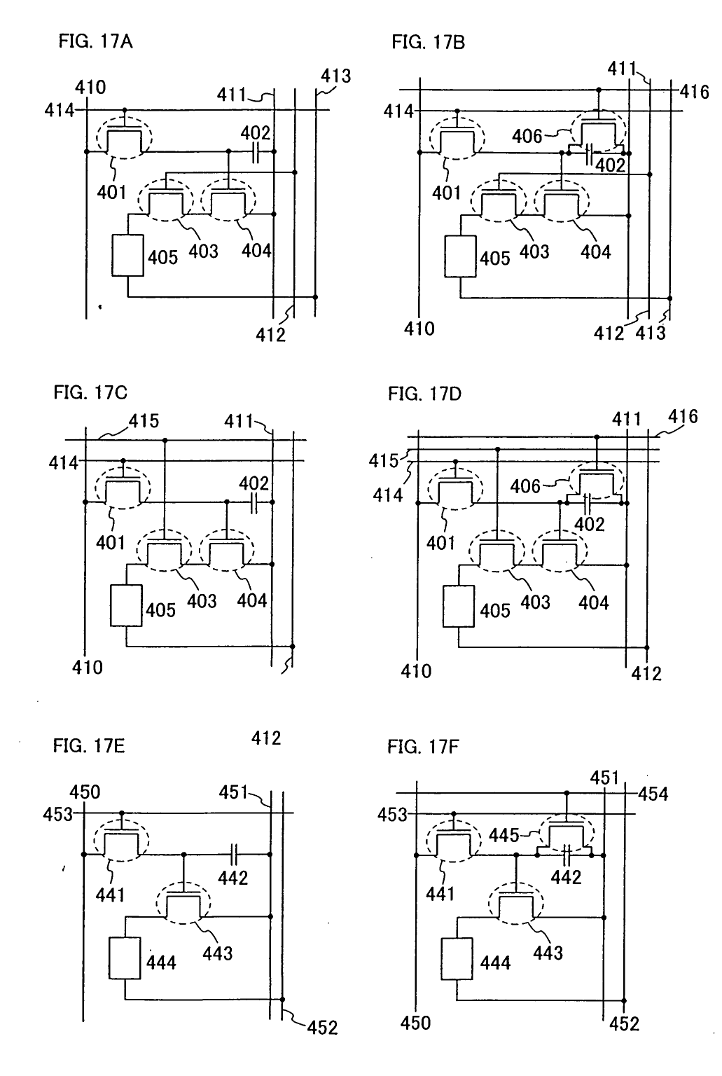

A structure of a pixel of a display panel shown in this embodiment is described with reference to equivalent circuit diagrams shown in FIGS. 17A to 17F.

In a pixel shown in FIG. 17A, a signal line 410 and power supply lines 411 to 413 are arranged in columns, and a scanning line 414 is arranged in a row. The pixel also includes a switching TFT 401, a driving TFT 403, a current controlling TFT 404, a capacitor element 402, and a light-emitting element 405.

A pixel shown in FIG. 17C has the same structure as the one shown in FIG. 17A, except that a gate electrode of the driving TFT 403 is connected to the power supply line 415 arranged in a row. Both pixels in FIGS. 17A and 17C show the same equivalent circuit diagrams. However, each power supply line is formed of conductive layers in different layers in between the cases where the power supply line 412 is arranged in a column (FIG. 17A) and where the power supply line 415 is arranged in a row (FIG. 17C). The two pixels are each shown in FIGS. 17A and 17C in order to show that layers in which a wiring connected to the gate electrode of the driving TFT 403 is formed are different in between FIGS. 17A and 17C.

In both FIGS. 17A and 17C, the TFTs 403 and 404 are connected in series in the pixel, and the ratio of the channel length L₃/the channel width W₃ of the TFT 403 to the channel length L₄/the channel width W₄ of the TFT 404 is set as L₃/W₃:L₄/W₄=5 to 6000:1. For example, when L₃, W₃, L₄, and W₄ are 500 μm, 3 μm, 3 μm, and 100 μm, respectively. According to the present invention, such a narrow wiring having 3 μm W₃ can be stably formed without a break since a pattern can be formed to have a desired shape with preferable controllability. Hence, a TFT having electric characteristics required for satisfactorily functioning such pixels shown in FIGS. 17A and 17C can be formed. As a result, a highly reliable display panel superior in display capability can be manufactured.

The TFT 403 is operated in a saturation region and controls the amount of current flowing in the light emitting element 405, whereas the TFT 404 is operated in a linear region and controls a current supplied to the light emitting element 405. The TFTs 403 and 404 preferably have the same conductivity in view of the manufacturing process. For the driving TFT 403, a depletion type TFT may be used instead of an enhancement type TFT. According to the invention having the above structure, slight variations in VGS of the TFT 404 does not affect the amount of current flowing in the light emitting element 405, since the current controlling TFT 404 is operated in a linear region. That is, the amount of current flowing in the light emitting element 405 is determined by the TFT 403 operated in a saturation region. Accordingly, it is possible to provide a display device in which image quality is improved by improving variations in luminance of the light emitting element due to the variation of the TFT properties.

The TFTs 401 of pixels shown in FIGS. 17A to 17D controls a video signal input to the pixel. When the switching TFT 401 is turned ON and a video signal is input to the pixel, the video signal is held in the capacitor element 402. Although the pixel includes the capacitor element 402 in FIGS. 17A to 17D, the invention is not limited thereto. When a gate capacitance or the like can serve as a capacitor for holding a video signal, the capacitor element 402 is not necessarily provided.

The light emitting element 405 has a structure in which an electroluminescent layer is sandwiched between a pair of electrodes. A pixel electrode and a counter electrode (an anode and a cathode) have a potential difference therebetween so that a forward bias voltage is applied. The electroluminescent layer is formed of wide range of materials such as an organic material, an inorganic material. The luminescence in the electroluminescent layer includes luminescence that is generated when an excited singlet state returns to a ground state (fluorescence) and luminescence that is generated when an exited triplet state returns to a ground state (phosphorescence).

A pixel shown in FIG. 17B has the same structure as the one shown in FIG. 17A, except that a TFT 406 and a scanning line 416 are added. Similarly, a pixel shown in FIG. 17D has the same structure as the one shown in FIG. 17C, except that a TFT 406 and a scanning line 416 are added.

The TFT 406 is controlled to be ON/OFF by the added scanning line 415. When the TFT 406 is turned ON, charges held in the capacitor element 402 are discharged, thereby turning the TFT 404 OFF. That is, supply of a current to the light emitting element 405 can be forcibly stopped by providing the TFT 406. Therefore, a lighting period can start simultaneously with or shortly after a writing period starts before signals are written into all the pixels by adopting the structures shown in FIGS. 17B and 17D, thus, the duty ratio can be improved.

In a pixel shown in FIG. 17E, a signal line 450 and power supply lines 451 and 452 are arranged in columns, and a scanning line 453 is arranged in a row. The pixel further includes a switching TFT 441, a driving TFT 443, a capacitor element 442, and a light emitting element 444. A pixel shown in FIG. 17F has the same structure as the one shown in FIG. 17E, except that a TFT 445 and a scanning line 454 are added. It is to be noted that the structure of FIG. 17F also allows a duty ratio to be improved by providing the TFT 445.

As described above, according to the invention, a pattern of a wiring or the like can be stably formed with preferable controllability without a break. Therefore, a TFT can be provided with high electric characteristics and reliability, and the invention can satisfactorily be used for an applied technique for improving display capacity of a pixel in accordance with the intended use.

### Embodiment Mode 8

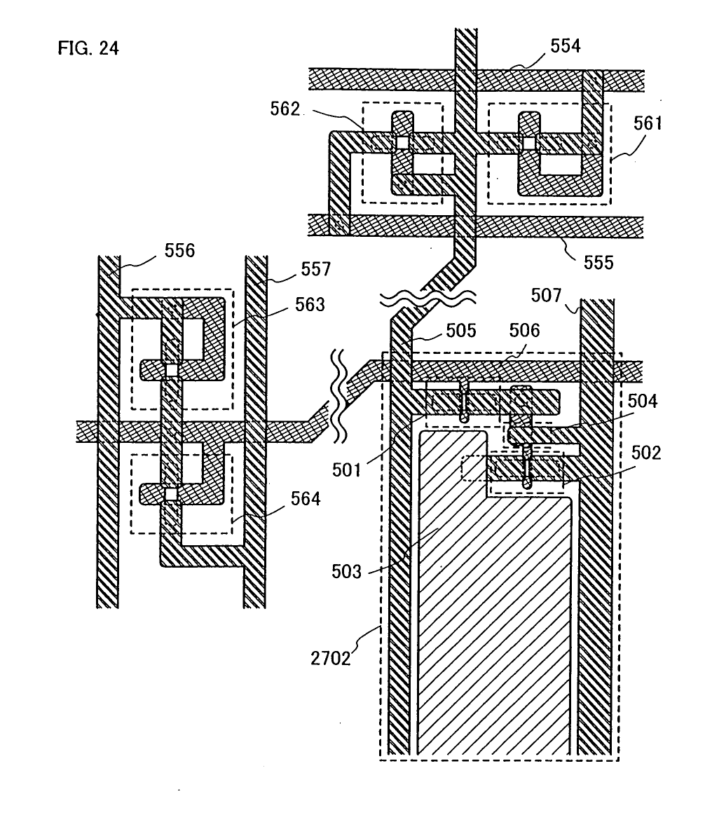

One mode in which protective diodes are provided for a scanning line input terminal portion and a signal line input terminal portion is explained with reference to FIG. 24. TFTs 501 and 502, a capacitor 504, and a light emitting element 503 are provided for a pixel 2702 in FIG. 24. This TFT has the same structure as that in Embodiment Mode 1.

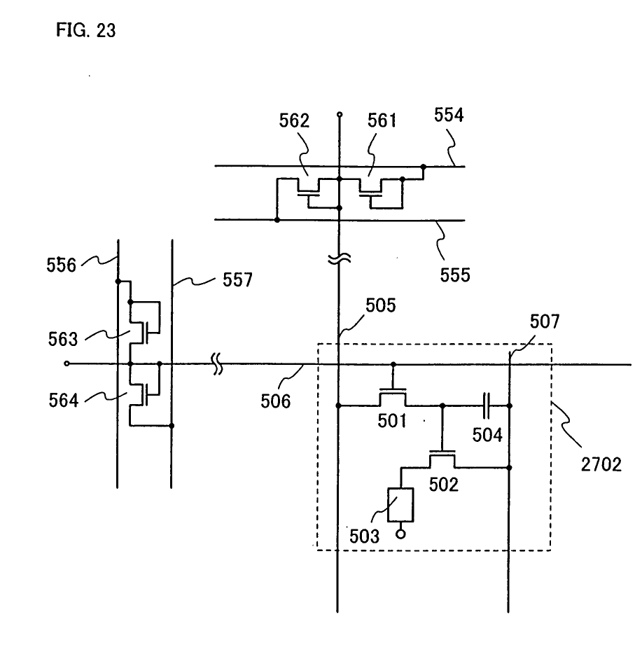

Protective diodes 261 and 262 are provided for the signal line input terminal portion. These protective diodes are manufactured in the same step as that of the TFT 260 and being operated as a diode by being each connected to a gate and one of a drain or a source. FIG. 23 shows an equivalent circuit diagram such as a top view shown in FIG. 24.

The protective diode 561 includes a gate electrode layer, a semiconductor layer, a wiring layer. The protective diode 562 has the same structure. Common potential lines 554 and 555 connecting to this protective diode are formed in the same layer as that of the gate electrode layer. Therefore, it is necessary to form a contact hole in the gate insulating layer to electrically connect to the wiring layer.

A mask layer may be formed and etching-processed to form a contact hole in the gate insulating layer. In this case, when etching-process at atmospheric pressure discharge is applied, electric discharging process can be locally performed, and a mask layer is not necessarily formed over the entire surface.

A signal wiring layer is formed in the same layer as that of a source/drain wiring layer 505 in the TFT 501 and has a structure in which the signal wiring layer connected thereto is connected to the source or drain side.

The input terminal portion of the scanning signal line side also has the same structure. A protective diode 563 includes a gate electrode layer, a semiconductor layer, and a wiring layer. A protective diode 564 also has the same structure. Common potential lines 556 and 557 connected to the protective diode are formed in the same layer as that of the source/drain wiring layer. According to the present invention, the protective diodes provided in an input stage can be formed at the same time. Note that the position of depositing a protective diode is not limited to this embodiment mode and can also be provided between a driver circuit and a pixel.

As described above, according to the invention, a pattern of a wiring or the like can be stably formed without generating a formation defect with preferable controllability. Therefore, even when a wiring or the like is complex and formed densely by forming a protective circuit, a short or the like due to the defect of installation at the time of formation is not generated. Additionally, the invention can correspond to a miniaturized or thinned device sufficiently since it is not necessary to take wide margin into consideration. As a result, a display device having preferable electric characteristics and high reliability can be manufactured.

### Embodiment Mode 9

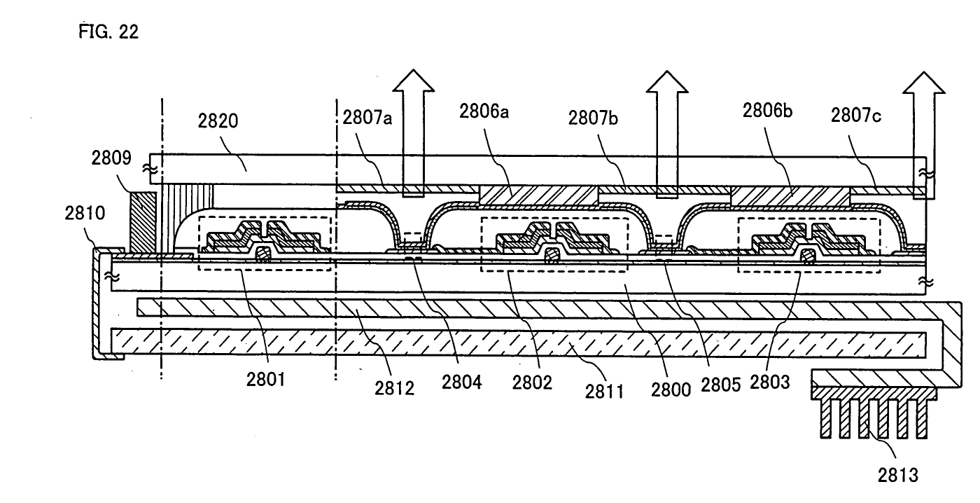

FIG. 22 shows an example constituting an EL display module having a TFT substrate 2800 manufactured according to the present invention. A pixel portion including pixels is formed over the TFT substrate 2800.

In FIG. 22, a TFT which is the same as that formed in a pixel or a protective circuit portion 2801 operated in the same manner as a diode by being connected to a gate and one of a source or a drain of the TFT is provided between a driver circuit and the pixel which is outside of the pixel portion. A driver IC formed of a single crystal semiconductor, a stick driver IC formed of a polycrystalline semiconductor film over a glass substrate, or a driver circuit formed of a SAS is applied to a driver circuit 2809.

The TFT substrate 2800 is bonded to a sealing substrate 2820 by interposing spacers 2806a and 2806b therebetween. The spacer is preferably provided to keep the space between two substrates constantly even when a substrate is thin and an area of a pixel portion is enlarged. A space between the TFT substrate 2800 and the sealing substrate 2820 over light emitting elements 2804 and 2805 connected to TFTs 2802 and 2803, respectively may be filled with a light-transmitting resin material and solidified, or may be filled with anhydrous nitrogen or an inert gas.

FIG. 22 shows the case in which the light emitting elements 2804 and 2805 have a structure of a top emission type and has a structure in which light is emitted in the direction of the arrow shown in the figure. Multicolor display can be carried out in each pixel by having different luminescent colors of red, green, and blue. In addition, at this time, color purity of the luminescence emitted outside can be enhanced by forming coloring layers 2807a, 2807b and 2807c corresponding to each color on the sealing substrate 2820 side. Moreover, the coloring layers 2807a, 2807b and 2807c may be combined by using the pixel as a white light emitting element.

The driver circuit 2809 and a wiring substrate 2810 are connected to each other through a scanning line or signal line connection terminal provided over one end of an external circuit substrate 2811. In addition, a heat pipe 2813 and a heat sink 2812 may be provided to be in contact with or close to the TFT substrate 2800 to have a structure improving a heat effect.

FIG. 22 shows the top emission type EL module, however, it may be a bottom emission structure by changing the structure of the light emitting element or the disposition of the external circuit substrate Naturally, a dual emission structure in which light is emitted to both sides of the top and bottom surfaces. In the case of the top emission structure, the insulating layer which is to be a partition wall may be colored to be used as a black matrix. This partition wall can be formed by a droplet discharge method or the like and it may be formed by mixing a black resin of a pigment material, carbon black, or the like into a resin material such as polyimide, or a lamination thereof may be also used.

Additionally, in the TFT substrate 2800, a sealing structure may be formed by attaching a resin film to the side where the pixel portion is formed with the use of a sealant or an adhesive resin. In this embodiment mode, glass sealing using a glass substrate is shown, however, various sealing methods such as resin sealing using a resin, plastic sealing using plastic, and film sealing using a film can be used. A gas barrier film which prevents moisture from penetrating is preferably provided on the surface of a resin film. By applying a film sealing structure, further thinner and lighter can be realized.

### Embodiment Mode 7

A television device can be completed by a display device formed according to the present invention. A display panel can be formed in any manners as follows: as the structure shown in FIG. 14A, in the case where only a pixel portion is formed, and then a scanning line driver circuit and a signal line driver circuit are mounted by a TAB method as shown in FIG. 15B; as the structure shown in FIG. 14A, in the case where only a pixel portion is formed, and then a scanning line driver circuit and a signal line driver circuit are mounted by a COG method as shown in FIG. 15A; a TFT is formed of a SAS, a pixel portion and a scanning line driver circuit are integrally formed over a substrate, and a signal line driver circuit is separately mounted as a driver IC as shown in FIG. 14B; and a pixel portion, a signal line driver circuit, and a scanning line driver circuit are integrally formed over the substrate as shown in FIG. 14C; or the like.

Another structure of an external circuit includes a video signal amplifier circuit which amplifies a video signal received by a tuner; a video signal processing circuit which converts the video signal output therefrom into a chrominance signal corresponding to each color of red, green, and blue; a control circuit which converts the video signal into an input specification of a driver IC; and the like on inputting side of the video signal. The control circuit outputs the signal into the scanning line side and the signal line side, respectively. In the case of digital driving, a signal division circuit may be provided on the signal line side so as to have a structure in which an input digital signal is provided by dividing into m-pieces.

Among a signal received from the tuner, an audio signal is transmitted to an audio signal amplifier circuit, and the output thereof is provided for a speaker through an audio signal processing circuit. A control circuit receives control information on a receiving station (a receiving frequency) or sound volume from an input portion and transmits the signal to the tuner or the audio signal processing circuit.

FIG. 13 shows an example of a liquid crystal display nodule, and a TFT 2600 and a counter substrate 2601 are fixed with a sealant 2602, with a pixel portion 2603 and a liquid crystal layer 2604 interposed therebetween to form a display region. Coloring layer 2605 is required in the case of performing a color display. In the case of an RGB method, coloring layers corresponding to red, green, and blue are provided for each pixel. Polarizing plates 2606 and 2607, an optical film 2613 are provided outside the TFT substrate 2600 and the counter substrate 2601. A light source includes a cold cathode tube 2610 and reflection plate 2611, and a circuit substrate 2612 is connected to the TFT substrate 2600 through a driver circuit 2608 and a flexible wiring substrate 2609 and an external circuit such as a control circuit or a power supply circuit is incorporated.

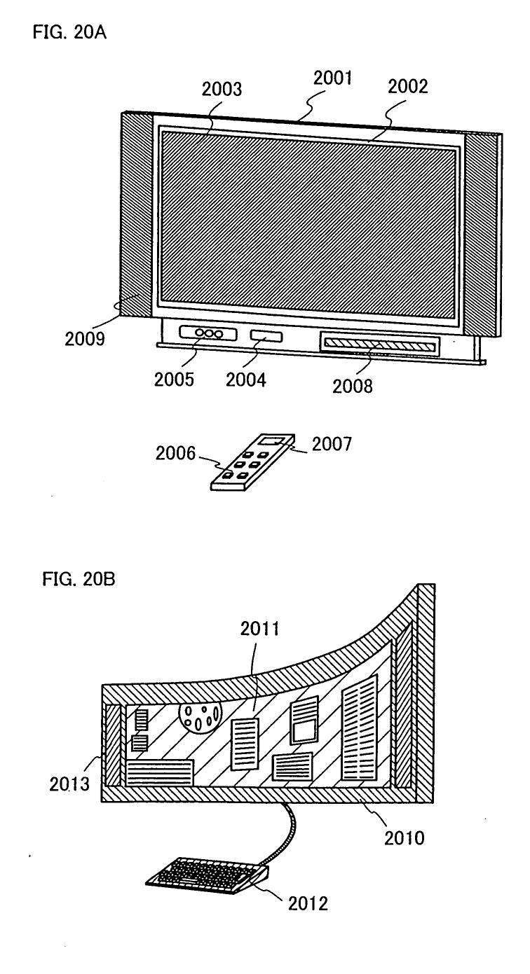

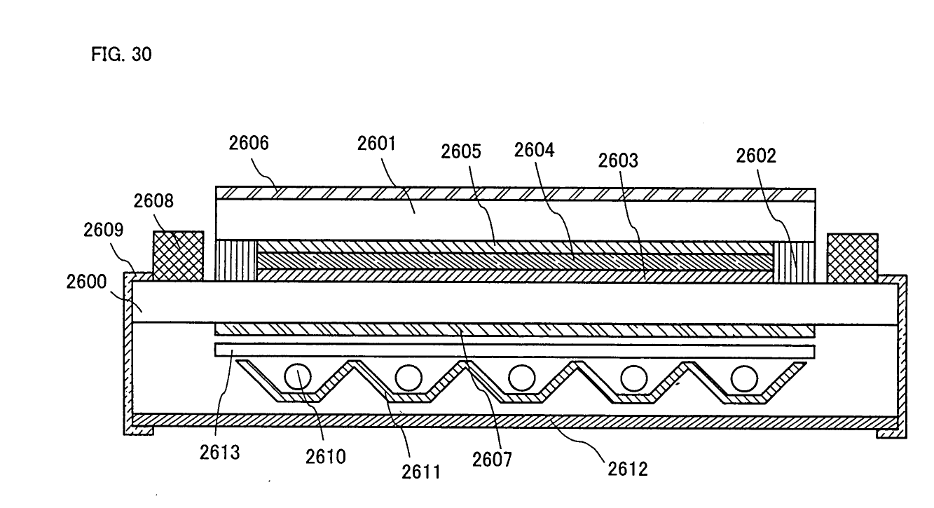

As shown in FIGS. 20A and 20B, a television device can be completed by incorporating a display module into a chassis 2001. An EL television device can be completed when an EL display module as in FIG. 22 is used, and a liquid crystal television device can be completed when a liquid crystal module as in FIG. 30 is used. A main screen 2003 is formed by using the display module, and a speaker portion 2009, operation switches, and the like are provided as other attached equipments. In such a manner, the television device can be completed according to the invention.

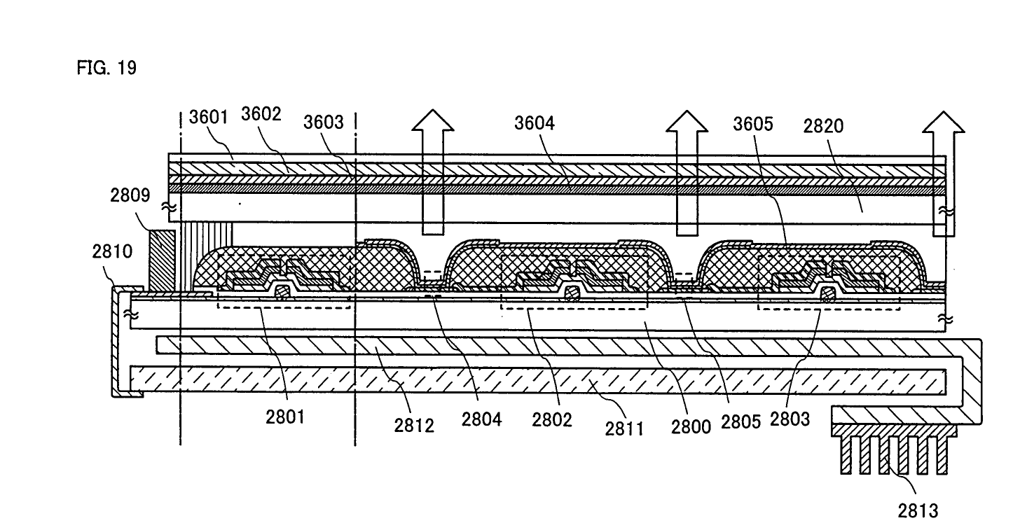

In addition, reflected light of light entered from exterior may be shielded by using a retardation film and a polarizing plate. FIG. 19 is a structure of a top emission type and an insulating layer 3605 which is to be a partition wall is colored to use as a black matrix. The partition wall can be formed by a droplet discharge method, and carbon black or the like may be mixed into a resin material such as polyimide, and a lamination thereof may be also used. Depending on a droplet discharge method, different materials may be discharged on the same region plural times to form the partition wall. In this embodiment mode, a black resin of a pigment is used. A λ/4 plate and a λ/2 plate may be used as retardation films 3603 and 3604 and may be designed to be able to control light. As the structure, a TFT element substrate 2800, a light emitting element 2804, a sealing substrate (sealant) 2820, a retardation films (λ/4 and λ/2) 3603 and 3604, a polarizing plate 3602 are sequentially laminated, in which light emitted from the light emitting element is emitted outside of the polarizing plate side to transmit them. The retardation film or polarizing plate may be provided on a side where light is emitted or may be provided on the both sides in the case of a dual emission type display device in which light is emitted from the both faces. In addition, an anti-reflective film 3601 may be provided on the outer side of the polarizing plate. Accordingly, a higher definition and more accurate image can be displayed.

As shown in FIG. 20A, a display panel 2002 using a display element is incorporated into a chassis 2001. By using a receiver 2005, in addition to receiving general TV broadcast, information communication can also be carried out in one direction (from a transmitter to a receiver) or in the both directions (between a transmitter and a receiver or between receivers) by connecting to a communications network by a fixed line or a wireless through a modem 2004. The operation of the television device can be carried out by switches incorporated into the chassis or by a remote control device 2006, which is separated from the main body. A display portion 2007 that displays information to be output may be also provided for this remote control device.

In addition, in the television device, a structure displaying a channel, sound volume, or the like may be additionally provided by forming a sub-screen 2008 of a second display panel in addition to the main screen 2003. In this structure, the main screen 2003 is formed of an EL display panel superior in a viewing angle, and the sub-screen may be formed of a liquid crystal display panel capable of displaying the sub-screen with low power consumption. In order to prioritize low power consumption, a structure in which the main screen 2003 is formed of a liquid crystal display panel, the sub-screen is formed of an EL display panel, and the sub-screen is able to flash on and off may be also applied. According to the invention, a display device with high reliability can be manufactured even by using many TFTs and electronic parts by using such a large-sized substrate.

FIG. 20B shows a television device having a large-sized display portion of, for example, 20 inches to 80 inches, which includes a chassis 2010, a keyboard portion 2011 which is an operation portion, a display portion 2012, a speaker portion 2013, and the like. The invention is applied to manufacturing the display portion 2012. FIG. 20B shows a television device having a curved display portion since a substance which is capable of curving is used for the display portion. Thus, a television device having a desired shape can be manufactured since the shape of the display portion can be freely designed.

Using the invention enables to simplify the process. Accordingly, a display panel can be easily manufactured even when a glass substrate which is in and after the fifth generation having 1000 mm or more on a side is used.

According to the invention, a desired pattern can be formed with preferable controllability and the loss of material and the cost can also be reduced. Hence, a television device even with a large screen display portion can be formed with low cost by using the invention, and a defect is not generated even when the television device is thinned and a wiring or the like becomes accurate. Accordingly, a high-performance and highly reliability television device can be manufactured with a preferable yield.

Naturally, the invention is not limited to the television device and it can be applied to various usages especially as the display mediums having a large area such as an information display board at a station, an airport, or the like, or an advertisement display board on the street as well as a monitor of a personal computer.

### Embodiment Mode 11

Various display devices can be manufactured by applying the present invention. In other words, the invention can be applied to various electronic devices in which these display devices are incorporated into display portions.

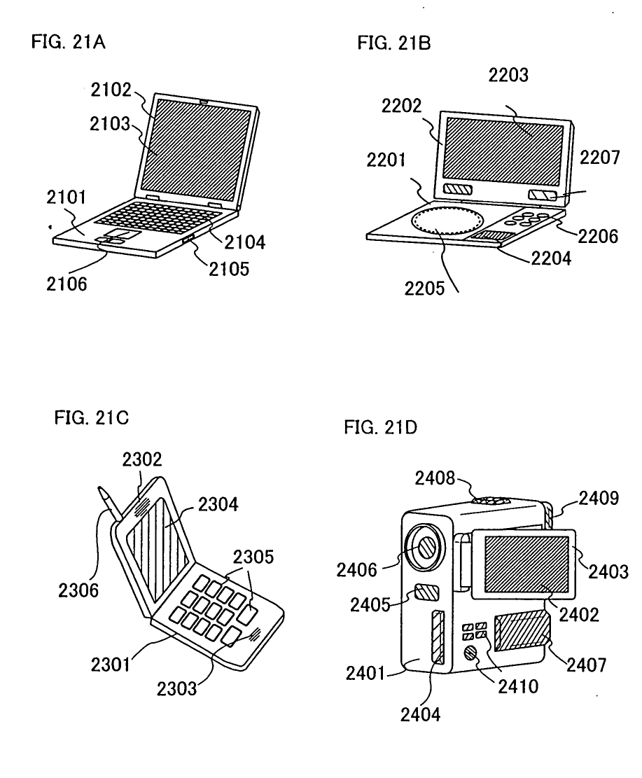

The electronic devices include a camera such as a video camera or a digital camera, a projector, a head mounted display (a goggle type display), a car navigation system, a car stereo, a personal computer, a game machine, a portable information terminal (a mobile computer, a cellular phone, an electronic book, or the like), an image reproducing device provided with a recording medium (specifically a device that is capable of playing a recording medium such as a Digital Versatile Disc (DVD) and that has a display device that can display the image) or the like. FIGS. 21A to 21D show the examples thereof.

FIG. 21A is a personal computer, which includes a main body 2101, a chassis 2102, a display portion 2103, a keyboard 2104, an external connection port 2105, a pointing mouse 2106 and the like. The invention is applied to manufacturing the display portion 2103. According to the invention, an image with high reliability and high resolution can be displayed even the personal computer is miniaturized and a wiring or the like becomes accurate.

FIG. 21B is an image reproducing device provided with a recording medium (specifically a DVD reproducing device), which includes a main body 2201, a chassis 2202, a display portion A 2203, a display portion B 2204, a recording medium (such as a DVD) reading portion 2205, operation keys 2206, a speaker portion 2207 and the like. The display portion A 2203 mainly displays image information and the display portion B 2204 mainly displays character information, and the invention is applied to manufacturing these display portions A 2203 and B 2204. According to the invention, an image with high reliability and high resolution can be displayed even when the image reproducing device is miniaturized and a wiring or the like becomes accurate.

FIG. 21C is a cellular phone, which includes a main body 2301, an audio output portion 2302, an audio input portion 2303, a display portion 2304, operation switches 2305, an antenna 2306, and the like. By applying the display device manufactured according to the invention to the display portion 2304, display with high reliability and high resolution can be made even when the cellular phone is miniaturized and a wiring or the like becomes accurate.

FIG. 11D is a video camera, which includes a main body 2401, a display portion 2402, a chassis 2403, an external connection port 2404, a remote control receiving portion 2405, an image receiving portion 2406, a battery 2407, an audio input portion 2408, operation keys 2409, eyepiece portion 2410, and the like. By applying the display device manufactured according to the invention to the display portion 2304, display with high reliability and high resolution can be made even when the video camera is miniaturized and a wiring or the like becomes accurate. This embodiment mode can be freely combined with the above-mentioned embodiment modes.

### Embodiment 1

In this embodiment, an effect of the present invention is explained based on experimental results.

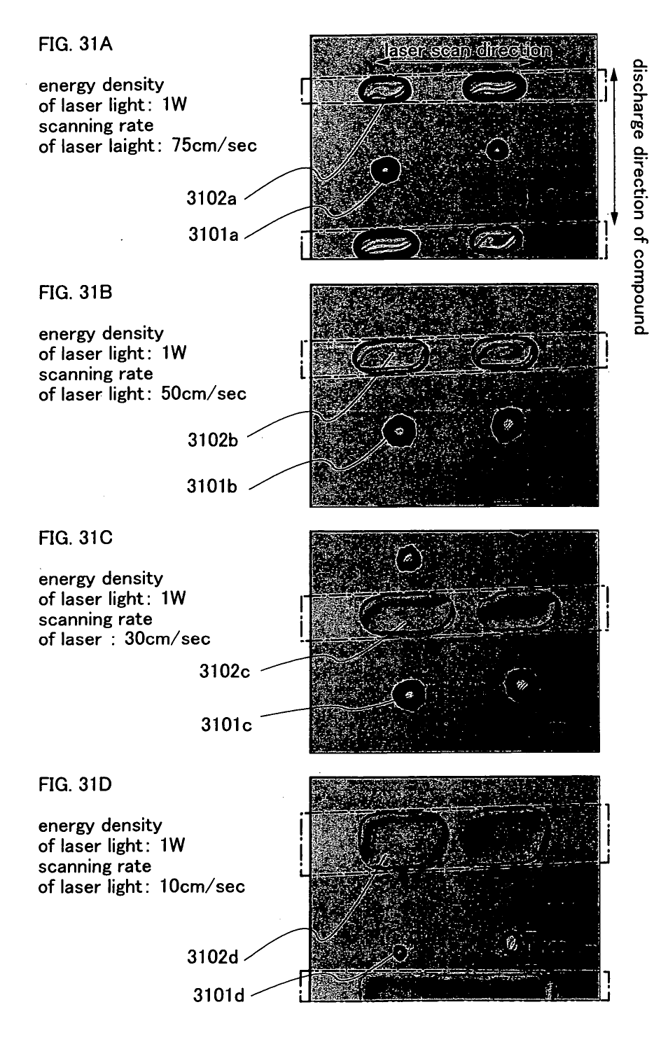

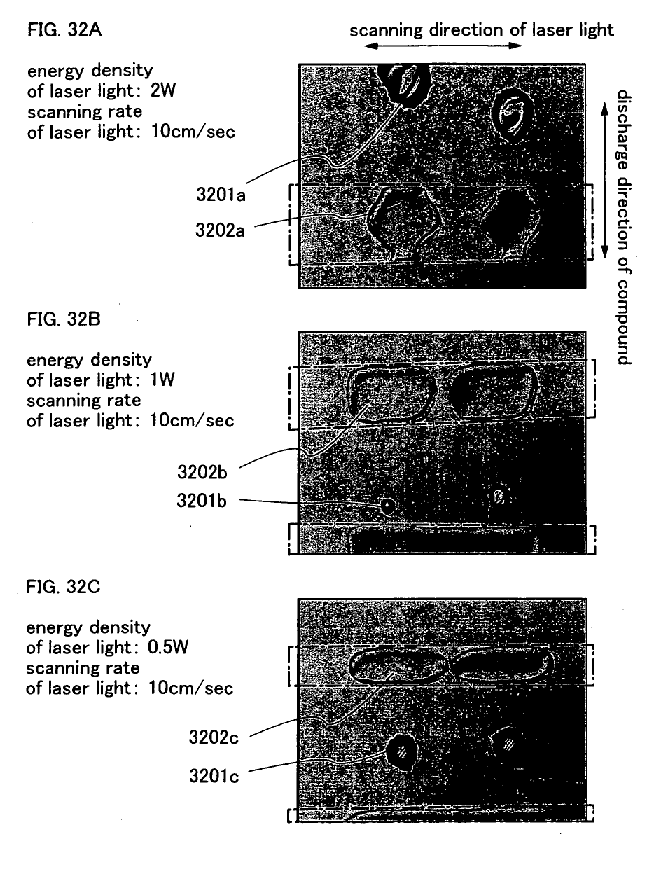

As shown in Embodiment Mode 1, a substrate was made to have low wettability by using a substance having low wettability. As the substance having low wettability, FAS which is a silane coupling agent was used, and rhodamine B which is a pigment was used as a light-absorbing material, which were diluted with isopropyl alcohol which is a solvent to make a compound having low wettability. The compound having low wettability was applied by a spin coating method. Rhodamine B which is a pigment having an absorption region in the laser light wavelength of 532 nm was used since YVO₄ laser having the wavelength of 532 nm was used. Rhodamine B was mixed until it was saturated to be a solution. The compound having low wettability was irradiated with laser light having the wavelength of 532 nm while a stage over which a processing object was installed was transferred to perform process. Afterwards, cleaning was performed with water to remove pigments to some extent, and a compound including a pattern forming material was discharged. The shapes of the compound of a region where laser light irradiation treatment was performed and a region where laser light irradiation treatment was not performed were observed. As the pattern forming material, polyimide was used, and the discharge condition was set as follows: a discharge frequency was 0.1 kHz; and a stage rate over which the substrate was installed, 1 cm/sec. The results are shown in FIGS. 31A to 31D and FIGS. 32A to 32D.

Photos of pattern in which laser light energy density was set at 1 W and laser light scanning rate was changed to be at (A) 75 cm/sec, (B) 50 cm/sec, (C) 30 cm/sec, and (D) 10 cm/sec taken by an optical microscope are shown in FIGS. 31A to 31D. Photos of pattern in which laser light scanning rate was set at 10 cm/sec and laser light energy density was changed to be at (A) 2 W, (B) 1 W, (C) 0.5 W taken by an optical microscope are shown in FIGS. 32A to 32C. The scanning direction of the laser light was in the lateral direction of the page, and the discharge direction of the compound including a pattern forming material was in the lengthwise direction of the page, which is the vertical direction thereof. The compound having low wettability was colored red which was the color of rhodamine B, and the color in the processed region where laser light was irradiated was faded. Pigments in a region which was not irradiated with laser light were almost removed, and pigments in a region which was irradiated with laser light were left by performing subsequent cleaning with the use of water. It is conceivable that the residual distribution of the pigments was obtained since the pigments could not be entirely removed with water cleaning which had weak dissolving power, and the pigments in a region which was irradiated with laser light obtained higher fixing power due to heat or the like. In the case of cleaning the pigments with ethanol having higher dissolving power, pigments in both the region which was irradiated with laser and the region which was not irradiated with laser were removed. The region which was irradiated with laser light was a region surrounded by a chain line. The color in the photos show the reverse color since observation was performed in the reflection bright-field. Cleaning with the use of only water was performed in examples shown in FIGS. 31A to 31D and FIGS. 32A to 32C; therefore, as described above, the pigments were not entirely removed in both the region which was irradiated with laser and the region which was not irradiated with laser. More pigments remain in the region which was irradiated with laser.

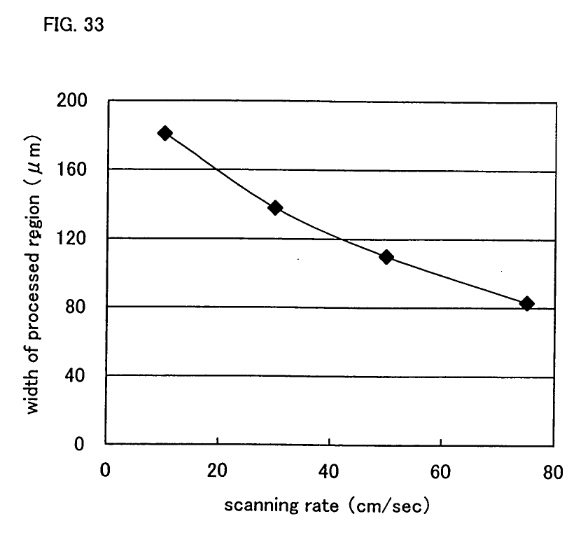

Table 1 shows the results of measuring the width of regions processed with laser light at each scanning rate of laser light. As the width of the processed regions, widths in three arbitrary regions were measured to obtain the average value. The graph in FIG. 33 shows the relation between the laser light scanning rate and the width of the region processed with the laser light.

TABLE 1

width of processed region (μm)

| scanning rate (cm/sec) | 1 | 2 | 3 | average |
|---|---|---|---|---|
| 75 | 75 | 86 | 89 | 83 |
| 50 | 113 | 110 | 106 | 110 |
| 30 | 138 | 138 | 138 | 138 |
| 10 | 188 | 181 | 175 | 181 |

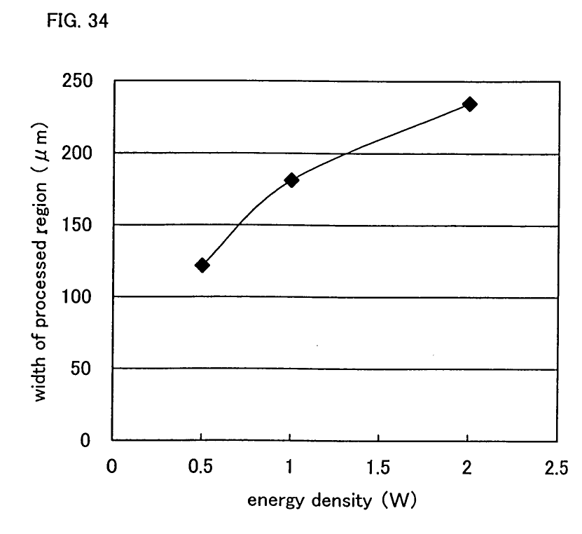

Table 2 shows the results of measuring the width of regions processed with laser light at each energy density of laser light. As the width of the processed regions, widths in three arbitrary regions were measured to obtain the average value. The graph in FIG. 34 shows the relation between the energy density of the laser light and the width of the region processed with the laser light.

TABLE 2

width of processed region (μm)

| energy density (W) | 1 | 2 | 3 | average |
|---|---|---|---|---|
| 2 | 240 | 236 | 228 | 235 |
| 1 | 188 | 181 | 175 | 181 |
| 0.5 | 119 | 122 | 124 | 122 |

The width of a region which was irradiated with laser light was affected by the scanning rate and the energy density of the laser light. As the scanning rate becomes slowly, or the energy density of the laser light becomes higher, energy radiated on one region increases; therefore, a region having high wettability was widely formed.

The pattern forming material was diffused along the high-wettability region which was the region processed with laser light to from pattern shapes such as a pattern 3102a, a pattern 3102b, a pattern 3102c, a pattern 3102d, a pattern 3202a, a pattern 3202b, and a pattern 3202c. In a region which was not processed with laser light, patterns were not diffused to form narrow and small pattern shapes such as a pattern 3101a, a pattern 3101b, a pattern 3101c, a pattern 3101d, a pattern 3201a, a pattern 3201b, and a pattern 3201c, The contact angle of the pattern forming material on the surface was 65° in the region which is not irradiated with laser light, whereas, it was 120 in the region which is irradiated with laser light, which shows higher wettability compared with the region which is not irradiated with laser light. In addition, the contact angle of water on the surface was 95° in the region which is not irradiated with laser light, whereas, it was 17 in the region which is irradiated with laser light, which shows higher wettability compared with the region which is not irradiated with laser light.

According to the above results, it is confirmed that wettability increases due to irradiation treatment with the use of laser light; therefore, a high-wettability region can be formed. According to the invention, the range of laser light choice is expanded since a light-absorbing material may be selected in accordance with the laser light. Additionally, laser light process can be sufficiently performed even when the laser light has small energy since the irradiation efficiency of the laser light can be enhanced. Hence, a device or the process is simplified, which leads to reducing the cost or time as well as increasing the productivity. As in this embodiment, when a substance is modified by laser light irradiation, a minute wiring, electrode, or the like can be freely formed with preferable controllability since minute process is made possible by the laser light.

1. A method for forming a pattern comprising:
forming a first region having a substance including a light-absorbing material;
forming a second region by modifying the surface of the first region by selectively irradiating the first region with laser light having a wavelength which is absorbed by the light-absorbing material; and
forming a pattern by discharging a compound including a pattern forming material to the second region.

2. The method according to claim 1, wherein the light-absorbing material is dissolved in the substance.

3. The method according to claim 1, wherein a pigment is used as the light-absorbing material and the pigment is dispersed in the substance.

4. The method according to claim 1, wherein the wavelength of the laser light is set at 532 nm, and rhodamine B, eosine Y, methyl orange, or rose bengal is used as the light-absorbing material.

5. The method according to claim 1, wherein the substance including the light-absorbing material includes a fluorocarbon chain.

6. The method according to claim 1, wherein a surface of the substance is modified so that the first region has higher wettablity than that of the second region with respect to the compound.

7. A method for forming a pattern comprising:
forming a first region having a substance including a light-absorbing material;
forming a second region by modifying the surface of the first region by selectively irradiating the first region with laser light having a wavelength which is absorbed by the light-absorbing material;
removing the light-absorbing material; and
forming a pattern by discharging a compound including a pattern forming material to the second region.

8. The method according to claim 7, wherein the light-absorbing material is dissolved in the substance.

9. The method according to claim 7, wherein a pigment is used as the light-absorbing material and the pigment is dispersed in the substance.

10. The method according to claim 7, wherein the wavelength of the laser light is set at 532 nm, and rhodamine B, eosine Y, methyl orange, or rose bengal is used as the light-absorbing material.

11. The method according to claim 7, wherein the substance including the light-absorbing material includes a fluorocarbon chain.

12. The method according to claim 7, wherein a surface of the substance is modified so that the first region has higher wettablity than that of the second region with respect to the compound.

13. A method for manufacturing a semiconductor device comprising:
forming a first region having a substance including a light-absorbing material;
forming a second region by modifying the surface of the first region by selectively irradiating the first region with laser light having a wavelength which is absorbed by the light-absorbing material; and
forming a pattern by discharging a compound including a pattern forming material to the second region.

14. The method according to claim 13, wherein a pigment is used as the light-absorbing material.

15. The method according to claim 13, wherein the substance including the light-absorbing material includes a fluorocarbon chain.

16. The method according to claim 13, wherein a surface of the substance is modified so that the first region has higher wettablity than that of the second region with respect to the compound.

17. The method according to claim 13, wherein the electrode layer is formed as a gate electrode layer.

18. A method for manufacturing a semiconductor device comprising:
forming a first region having a substance including a light-absorbing material;
forming a second region by modifying the surface of the first region by selectively irradiating the first region with laser light having a wavelength which is absorbed by the light-absorbing material;
removing the light-absorbing material; and
forming a pattern by discharging a compound including a pattern forming material to the second region.

19. The method according to claim 18, wherein a pigment is used as the light-absorbing material.

20. The method according to claim 18, wherein the substance including the light-absorbing material includes a fluorocarbon chain.

21. The method according to claim 18, wherein a surface of the substance is modified so that the first region has higher wettablity than that of the second region with respect to the compound.

22. The method according to claim 18, wherein the electrode layer is formed as a gate electrode layer.

23. A semiconductor device comprising:
at least one thin film transistor over a substrate, the thin film transistor comprising:
an electrode layer provided over an insulating surface having a first region and a second region,
wherein the first region and the second region comprise a substance including a light-absorbing material,
wherein the electrode layer is provided over the second region, and
wherein the second region has higher wettability than that of the first region with respect to the electrode layer.

24. The semiconductor device according to claim 23, wherein the light-absorbing material is a pigment.

25. A semiconductor device comprising:
at least one thin film transistor over a substrate,
the thin film transistor comprising:
an electrode layer provided over an insulating surface having a first region and a second region,
wherein the second region comprises a substance including a light-absorbing material,
wherein the electrode layer is provided over the second region, and
wherein the second region has higher wettability than that of the first region with respect to the electrode layer.

26. The semiconductor device according to claim 25, wherein the light-absorbing material is a pigment.

27. A television device comprising:
a display device, the display device comprising:
a thin film transistor comprising a gate electrode layer provided over an insulating surface having a first region and a second region,
wherein the first region and the second region comprise a substance including a light-absorbing material,
wherein the gate electrode layer is provided over the second region, and wherein the second region has higher wettability than that of the first region with respect to the gate electrode layer.

28. The television device according to claim 27, wherein the light-absorbing material is a pigment.

29. A television device comprising:
a display device, the display device comprising:
a thin film transistor comprising a gate electrode layer provided over an insulating surface having a first region and a second region,
wherein the second region comprises a substance including a light-absorbing material,
wherein the gate electrode layer is provided over the second region, and
wherein the second region has higher wettability than that of the first region with respect to the gate electrode layer.

30. The television device according to claim 29, wherein the light-absorbing material is a pigment.
